(19) United States
(12) Patent Application Publication
(10) Pub. No.: US 2026/0343860 A1
(43) Pub. Date: Oct. 29, 2026

(54) SEMICONDUCTOR DEVICE INCLUDING A DUMMY STRUCTURE

(71) Applicant: Samsung Electronics Co., Ltd., Suwon-si (KR)

(72) Inventor: Jongin Kang, Suwon-si (KR)

(73) Assignee: Samsung Electronics Co., Ltd., Suwon-si (KR)

(21) Appl. No.: 19/564,956

(22) Filed: Mar. 12, 2026

(30) Foreign Application Priority Data
Apr. 29, 2025 (KR) 10-2025-0055951

(51) Int. Cl. H10B 12/00

(52) U.S. Cl. CPC H10B 12/482; H10B 12/50

(57) ABSTRACT

A semiconductor device includes a substrate having a cell array region having a cell active region, a peripheral circuit region, and a connection region between the cell array region and the peripheral circuit region; gate structures including a gate electrode extending in a first direction crossing the cell active region on the cell array region and extending into the connection region, each of the gate structures being spaced apart from one another in a second direction substantially perpendicular to the first direction; a bitline structure extending in the second direction intersecting the cell array region and connected to the cell active region; a dummy bitline structure extending in the second direction on the connection region; dummy structures disposed on the connection region and penetrating the dummy bitline structure, wherein the dummy bitline structure has different widths taken in the first direction in the second direction.

### CROSS-REFERENCE TO RELATED APPLICATIONS

This present application claims priority to and the benefit under 35 U.S.C. § 119(a)-(d) of Korean Patent Application No. 10-2025-0055951, filed on Apr. 29, 2025, in the Korean Intellectual Property Office, the entire disclosure of which is incorporated herein by reference.

### FIELD

Example embodiments of the present disclosure relate to a semiconductor device and more particularly to a semiconductor device including a dummy structure, and to a method of manufacturing the same.

### BACKGROUND

With the development of the electronics industry and user demand, electronic devices have been designed to have a reduced size and high performance. Accordingly, semiconductor devices used in electronic devices have also been required to have high integration density. To manufacture highly scaled semiconductor devices, techniques for creating an alleviated environmental difference between regions have been necessary.

### SUMMARY

Example embodiments of the present disclosure is to provide a semiconductor device having improved reliability and performance.

According to example embodiments of the present disclosure, a semiconductor device includes a substrate including a cell array region, a peripheral circuit region, and a connection region between the cell array region and the peripheral circuit region; a device isolation region including a cell device isolation region defining a cell active region on the cell array region and a connection device isolation region defining an active region on the connection region, on the substrate; a gate structure including a gate electrode crossing the cell active region on the cell array region and extending into the connection device isolation region of the device isolation region on the connection region; a bitline structure extending in a first direction intersecting the gate structure on the cell array region and connected to the cell active region; a dummy bitline structure extending in the first direction on the connection region and having at least a portion disposed at substantially a same level as a level of the bitline structure; an insulating structure disposed on the dummy bitline structure on the connection region; and dummy structures disposed on the connection region and penetrating at least a portion of the insulating structure, wherein the dummy structures include a first dummy structure disposed on the connection device isolation region; and a second dummy structure spaced apart from the first dummy structure in the first direction, vertically overlapping the gate structure, and having at least a portion disposed at substantially a same level as a level of the bitline structure.

According to example embodiments of the present disclosure, a semiconductor device includes a substrate including a cell array region having a cell active region, a peripheral circuit region, and a connection region between the cell array region and the peripheral circuit region; gate structures including a gate electrode extending in a first direction crossing the cell active region on the cell array region and extending into the connection region, the gate structures being spaced apart from one another in a second direction substantially perpendicular to the first direction; a bitline structure extending in the second direction intersecting the gate structures on the cell array region, and connected to the cell active region; a dummy bitline structure extending in the second direction on the connection region; an insulating structure including an insulating liner covering an upper portion and a side portion of the dummy bitline structure and extending along upper surfaces of the gate structures, and an interlayer insulation layer on the insulating liner; and dummy patterns on the connection region, wherein the dummy patterns include at least one first dummy pattern penetrating the insulating structure and the dummy bitline structure between the gate structures; and at least one second dummy pattern vertically overlapping the gate structures and penetrating the insulating structure and the dummy bitline structure.

According to example embodiments of the present disclosure, a semiconductor device includes a substrate having a cell array region having a cell active region, a peripheral circuit region, and a connection region between the cell array region and the peripheral circuit region; gate structures including a gate electrode extending in a first direction crossing the cell active region on the cell array region and extending into the connection region, each of the gate structures being spaced apart from one another in a second direction perpendicular to the first direction; a bitline structure extending in the second direction intersecting the cell array region and connected to the cell active region; a dummy bitline structure extending in the second direction on the connection region; dummy structures disposed on the connection region and penetrating the dummy bitline structure, wherein the dummy bitline structure has different widths taken in the first direction in the second direction.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan diagram illustrating a semiconductor device according to example embodiments of the present disclosure;

FIGS. 2A and 2B are enlarged diagrams illustrating a portion of a semiconductor device according to example embodiments of the present disclosure;

FIGS. 3A, 3B, 3C, and 3D are cross-sectional diagrams illustrating a semiconductor device according to example embodiments of the present disclosure;

FIG. 4 is a plan diagram illustrating a semiconductor device according to example embodiments of the present disclosure;

FIG. 5 is a plan diagram illustrating a semiconductor device according to example embodiments of the present disclosure;

FIG. 6 is a plan diagram illustrating a semiconductor device according to example embodiments of the present disclosure;

FIGS. 7A and 7B are cross-sectional diagrams illustrating a semiconductor device according to example embodiments of the present disclosure;

FIGS. 8A and 8B are enlarged diagrams illustrating a portion of a semiconductor device according to example embodiments of the present disclosure;

FIG. 9 is a plan diagram illustrating a semiconductor device according to example embodiments of the present disclosure;

FIGS. 10A and 10B are cross-sectional diagrams illustrating a semiconductor device according to example embodiments of the present disclosure;

FIG. 11 is a plan diagram illustrating a semiconductor device according to example embodiments of the present disclosure;

FIGS. 12A and 12B are cross-sectional diagrams illustrating a semiconductor device according to example embodiments of the present disclosure;

FIG. 13 is a plan diagram illustrating a semiconductor device according to example embodiments of the present disclosure;

FIGS. 14A and 14B are cross-sectional diagrams illustrating a semiconductor device according to example embodiments of the present disclosure;

FIG. 15 is a plan diagram illustrating a semiconductor device according to example embodiments of the present disclosure;

FIGS. 16A, 16B, 16C, 16D, FIGS. 17A and 17B, and FIGS. 18A, 18B, 18C, and 18D are cross-sectional diagrams illustrating processes of a method of manufacturing a semiconductor device in order according to example embodiments of the present disclosure; and

FIGS. 19A and 19B, FIGS. 20A and 20B, and FIGS. 21A and 21B are cross-sectional diagrams illustrating processes of a method of manufacturing a semiconductor device in order according to example embodiments of the present disclosure.

### DETAILED DESCRIPTION

Hereinafter, embodiments of the present disclosure will be described as follows with reference to the accompanying drawings.

The terms such as “upper,” “upper portion,” “upper surface,” “lower,” “lower portion,” “lower surface,” “side surface,” “upper end,” and “lower end” may be referred to based on the drawings, unless otherwise indicated. The terms such as “upper portion,” “intermediate portion,” and “lower portion,” or the like, may be replaced with other terms, for example, “first,” “second,” and “third,” and may be used to describe elements in the embodiments. The terms such as “first,” “second,” and “third” may be used to describe various elements, but the elements are not limited to the terms, and a “first component” may be denoted as a “second component.”

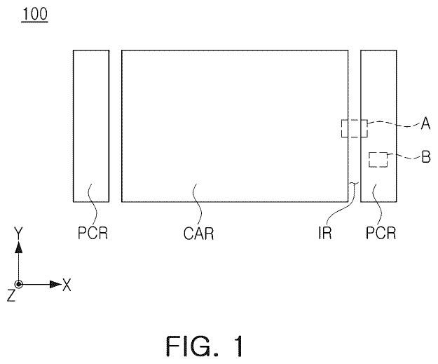

FIG. 1 is a plan diagram illustrating a semiconductor device according to example embodiments.

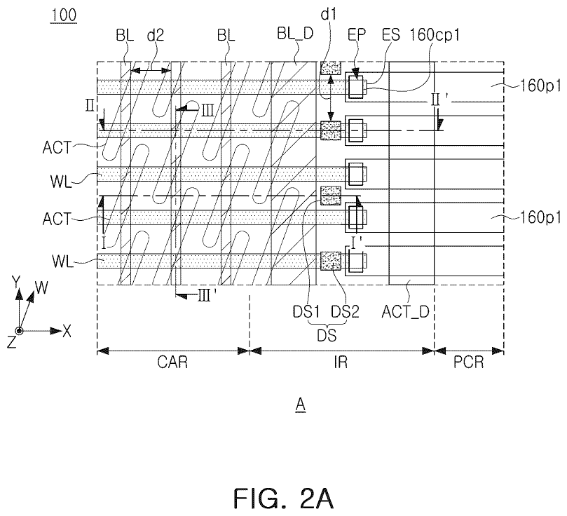

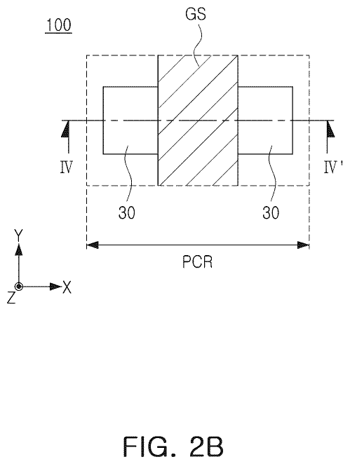

FIGS. 2A and 2B are enlarged diagrams illustrating a portion of a semiconductor device according to example embodiments. FIG. 2A is an enlarged diagram illustrating region “A” in FIG. 1, and FIG. 2B is an enlarged diagram illustrating region “B” in FIG. 1.

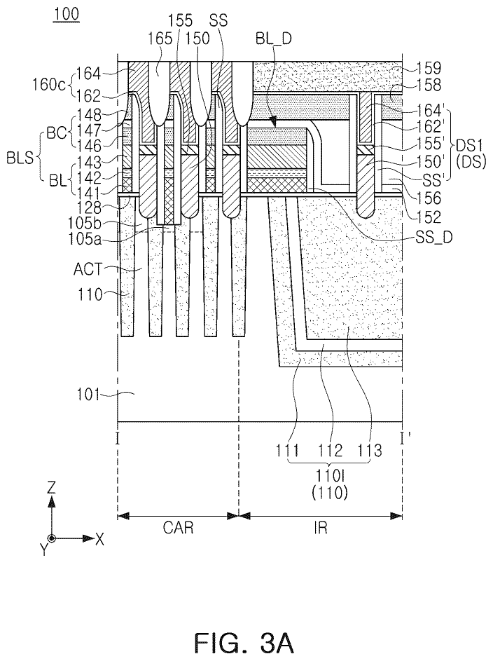

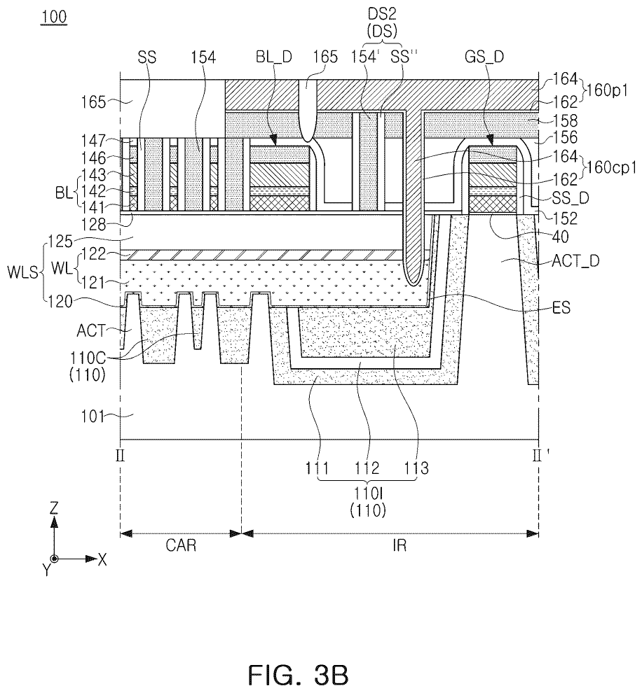

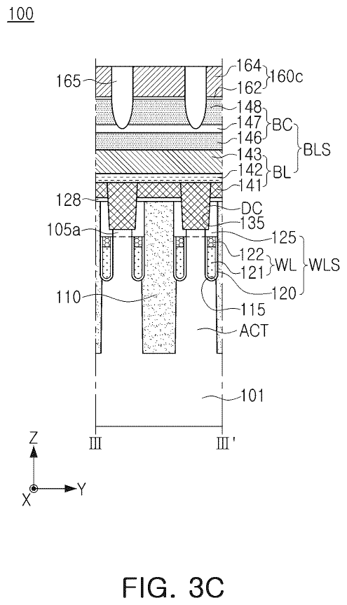

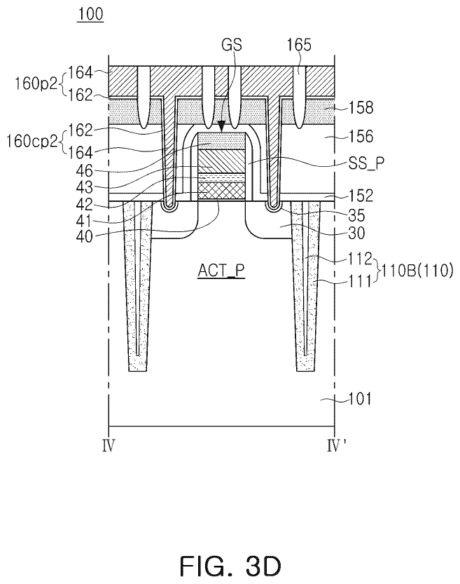

FIGS. 3A, 3B, 3C, and 3D are cross-sectional diagrams illustrating a semiconductor device according to example embodiments. FIG. 3A is a cross-sectional diagram taken along line I-I′ in FIG. 2A. FIG. 3B is a cross-sectional diagram taken along line II-II′ in FIG. 2A. FIG. 3C is a cross-sectional diagram taken along line III-III′ in FIG. 2A. FIG. 3D is a cross-sectional diagram taken along line IV-IV′ in FIG. 2B.

Referring to FIGS. 1, 2A and 2B, a semiconductor device 100 may include a cell array region CAR, a peripheral circuit region PCR for driving the cell array region CAR, and a connection region IR between the cell array region CAR and the peripheral circuit region PCR. In example embodiments, the regions CAR, PCR, and IR may be defined on the substrate 101. In the cell array region CAR, memory cells may be disposed. The peripheral circuit region PCR may be disposed around the cell array region CAR. In the peripheral circuit region PCR, a wordline driver, a sense amplifier, row and column decoders, and control circuits may be disposed. The connection region IR may be provided to electrically connecting the cell array region CAR to the peripheral circuit region PCR. In an example, in the connection region IR, the wordline WL may be connected to a contact plug 160cp1, and the contact plug 160cp1 may be connected to an upper conductive pattern 160p1.

Referring to FIGS. 1, 2A, 2B, 3A, 3B, 3C, and 3D, the semiconductor device 100 may include a substrate 101 including active regions ACT, a device isolation region 110 defining active regions ACT in the substrate 101, a wordline structure WLS extending by being buried in the substrate 101 and including a wordline WL, a bitline structure BLS extending across the wordline structure WLS on the substrate 101 and including a bitline BL, and a dummy bitline structure BL_D. The active regions ACT, the wordline structure WLS, and the bitline structure BLS may be disposed in the cell array region CAR. The dummy bitline structure BL_D may be disposed in the connection region IR. The dummy bitline structure BL_D may be referred to as a dummy bitline.

The semiconductor device 100 may further include a lower conductive pattern 150 on the active region ACT, a first upper conductive pattern 160c on the lower conductive pattern 150, a contact plug 160cp1 connected to the wordline WL in the connection region IR, a second upper conductive pattern 160p1 on the contact plug 160cp1, a peripheral contact plug 160cp2 connected to a peripheral source/drain region 30 in the peripheral circuit region PCR, a third upper conductive pattern 160p2 on the peripheral contact plug 160cp2, and an insulating pattern 165 penetrating the upper conductive patterns 160c, 160p1, and 160p2.

The semiconductor device 100 may further include a peripheral transistor disposed on the substrate 101 in the connection region IR and the peripheral circuit region PCR, an insulating liner 152, and interlayer insulating layers 156 and 158. In example embodiments, the insulating liner 152 and the interlayer insulating layers 156 and 158 may be collectively referred to as an insulating structure. The peripheral transistor may include a peripheral gate dielectric layer 40, peripheral circuit gate electrodes 41, 42, and 43, and peripheral source/drain regions 30.

The semiconductor device 100 may include dummy structures DS on the connection region IR. The dummy structures DS may include a first dummy structure DS1 disposed between the wordline structures WLS adjacent to one another and a second dummy structure DS2 vertically overlapping the wordline structure WLS. In example embodiments, the dummy structure DS may be referred to as a dummy pattern, the first dummy structure DS1 may be referred to as a first dummy pattern, and the second dummy structure DS2 may be referred to as a second dummy pattern.

The semiconductor device 100 may include, for example, a cell array of a DRAM (dynamic random access memory). For example, the bitline BL may be connected to the first impurity region 105a of the active region ACT, and the second impurity region 105b of the active region ACT may be electrically connected to a capacitor structure on the first upper conductive pattern 160c through lower and upper conductive patterns 150 and 160c. Although not illustrated, the capacitor structure may include, for example, a lower electrode, a capacitor dielectric layer, and an upper electrode, and the structure thereof is not limited thereto.

The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may further include impurities. The substrate 101 may be a silicon substrate, a silicon-on-insulator (SOI) substrate, a germanium substrate, a germanium on insulator (GOI) substrate, a silicon-germanium substrate, or a substrate including an epitaxial layer.

The active regions ACT may be defined in the substrate 101 by the device isolation region 110. The active region ACT may have a bar shape and may have an island shape extending in one direction, for example, in the W direction, in the substrate 101. The W direction may be an inclined direction with respect to the extending direction of the wordlines WL and the bitlines BL. The active regions ACT may be arranged to be parallel to one another, and an end of one active region ACT may be arranged adjacent to the center of another active region ACT adjacent thereto.

The active region ACT may have first and second impurity regions 105a and 105b having a predetermined depth from an upper surface of the substrate 101. The first and second impurity regions 105a and 105b may be spaced apart from one another. The first and second impurity regions 105a and 105b may be provided as source/drain regions of a transistor formed by the wordline WL. For example, a drain region may be formed between two wordlines WL crossing one active region ACT, and a source region may be formed externally of the two wordlines WL, respectively. The source region and the drain region may be formed by the first and second impurity regions 105a and 105b by doping or ion implantation of substantially the same impurities, and may be referred to interchangeably depending on the circuit configuration of the transistor to be finally formed. The impurities may include dopants having a conductivity-type opposite to that of the substrate 101. In example embodiments, the depths of the first and second impurity regions 105a and 105b in the source region and the drain region may be different.

The device isolation region 110 may be formed by a shallow trench isolation (STI) process. The device isolation region 110 may surround the active regions ACT and may electrically isolate the active regions ACT from one another. The device isolation region 110 may be formed of an insulating material, for example, silicon oxide, silicon nitride, or a combination thereof. The device isolation region 110 may include a plurality of regions having different lower-end depths depending on a width of the trench in which the substrate 101 is etched.

The device isolation region 110 may include a cell device isolation region 110C defining a cell active region ACT on a cell array region CAR, a peripheral device isolation region 110B defining a peripheral active region ACT_P on a peripheral circuit region PCR, and a connection device isolation region 110I defining a dummy active region ACT_D on a connection region IR. The dummy active region ACT_D may protrude from the substrate 101, and an upper surface of the dummy active region ACT_D may be disposed at substantially the same level as an upper surface of the gate capping layer 125. A dummy gate structure GS_D may be disposed on the dummy active region ACT_D, but example embodiments thereof is not limited thereto.

The device isolation region 110 may include a plurality of layers on the connection region IR, and for example, the connection device isolation region 110I may include a first insulating liner 111, a second insulating liner 112, and a filling insulating layer 113 in a region adjacent to the end portion EP of the wordline WL as illustrated in FIGS. 3A and 3B. The second insulating liner 112 may be disposed on the first insulating liner 111, and the filling insulating layer 113 may be disposed on the second insulating liner 112, the first insulating liner 111 and the second insulating liner 112 may be formed conformally along a surface of the trench in sequence in the etched trench of the substrate 101 in which the connection device isolation region 110I is disposed. A filling insulating layer 113 may fill a space in the trench which is not filled with the first and second insulating liners 111, 112. The second insulating liner 112 may include an insulating material different from that of the first insulating liner 111, and the filling insulating layer 113 may include an insulating material different from that of the second insulating liner 112. For example, the first insulating liner 111 and the filling insulating layer 113 may include silicon oxide, and the second insulating liner 112 may include silicon nitride.

The wordline structures WLS may be disposed in gate trenches 115 extending in the substrate 101. Each of the wordline structures WLS may include a gate dielectric layer 120, a wordline WL, and a gate capping layer 125. In example embodiments, ‘gate 120, WL’ may be referred to as a structure including the gate dielectric layer 120 and the wordline WL, the wordline WL may be referred to as a ‘gate electrode,’ and the wordline structure WLS may be referred to as a ‘gate structure.’

The wordline WL may intersect the active region ACT and may extend in the first direction X. For example, a pair of wordlines WL adjacent to one another may be disposed to cross the active region ACT. The wordline WL may form a gate of a buried channel array transistor (BCAT), but example embodiments thereof is not limited thereto. In example embodiments, the wordlines WL may also be disposed in an upper portion of the substrate 101. The wordline WL may be disposed in a lower portion of the gate trench 115 with a predetermined thickness. An upper surface of the wordline WL may be positioned at a level lower than a level of an upper surface of the substrate 101. In example embodiments, the term “level” is defined with respect to an upper surface of the substrate 101, which is substantially flat.

The wordline WL may include at least one of a conductive material, for example, polycrystalline silicon (Si), titanium (Ti), titanium nitride (TiN), tantalum (Ta), tantalum nitride (TaN), tungsten (W), tungsten nitride (WN), or aluminum (Al). For example, the wordline WL may include a lower pattern 121 and an upper pattern 122 formed of different materials.

For example, the lower pattern 121 may include at least one of tungsten (W), titanium (Ti), tantalum (Ta), tungsten nitride (WN), titanium nitride (TiN), or tantalum nitride (TaN). For example, the upper pattern 122 may be a semiconductor pattern including polysilicon doped with P-type or N-type impurities, and the lower pattern 121 may be a metal pattern including at least one of a metal or metal nitride. A thickness of the lower pattern 121 may be greater than a thickness of the upper pattern 122. Each of the lower pattern 121 and the upper pattern 122 may extend in the first direction X.

The gate dielectric layer 120 may be disposed on a bottom surface and internal side surfaces of the gate trench 115. The gate dielectric layer 120 may conformally cover an inner sidewall of the gate trench 115. The gate dielectric layer 120 may include at least one of silicon oxide, silicon nitride, or silicon oxynitride. The gate dielectric layer 120 may be, for example, silicon oxide or an insulating film having a high-κ. In example embodiments, the gate dielectric layer 120 may be formed by oxidizing the active region ACT, or may be formed by deposition.

The gate capping layer 125 may be disposed to fill the gate trench 115 on an upper portion of the wordline WL. An upper surface of the gate capping layer 125 may be positioned at substantially the same level as an upper surface of the substrate 101. The gate capping layer 125 may be formed of an insulating material, for example, silicon nitride.

The bitline structure BLS may extend in one direction substantially perpendicular to the wordline WL, for example, in the Y-direction. The bitline structure BLS may include a bitline BL and bitline capping patterns BC on the bitline BL. The bitline structure BLS may be disposed on the cell array region CAR.

The dummy bitline structure BL_D may extend in a direction parallel to the direction in which the bitline structure BLS extends, for example, in the Y-direction. The dummy bitline structure BL_D may be disposed on the connection region IR. The dummy bitline structure BL_D may have a structure similar to the bitline structure BLS, other than the configuration in which the dummy bitline structure BL_D has a greater width in the X-direction than that of the bitline structure BLS.

The bitline BL may include a first conductive pattern 141, a second conductive pattern 142, and a third conductive pattern 143, stacked in order. The bitline capping pattern BC may be disposed on the third conductive pattern 143. A buffer insulating layer 128 may be disposed between the first conductive pattern 141 and the substrate 101, and one portion of the first conductive pattern 141 (hereinafter, the bitline contact pattern DC) may be in contact with the first impurity region 105a of the active region ACT. The bitline BL may be electrically connected to the first impurity region 105a through the bitline contact pattern DC. A lower surface of the bitline contact pattern DC may be positioned at a level lower than a level of an upper surface of the substrate 101 and may be positioned at a level higher than a level of an upper surface of the wordline WL. In example embodiments, the bitline contact pattern DC may be locally disposed in a bitline contact hole 135 formed in the substrate 101 and exposing the first impurity region 105a.

The first conductive pattern 141 may include a semiconductor material, such as polycrystalline silicon. The first conductive pattern 141 may be in direct contact with the first impurity region 105a. The second conductive pattern 142 may include a metal-semiconductor compound. The metal-semiconductor compound may be, for example, a layer formed by siliciding a portion of the first conductive pattern 141. For example, the metal-semiconductor compound may include cobalt silicide (CoSi), titanium silicide (TiSi), nickel silicide (NiSi), tungsten silicide (WSi), or other metal silicides. The third conductive pattern 143 may include a metal material such as titanium (Ti), tantalum (Ta), tungsten (W), or aluminum (Al). The number of conductive patterns included in the bitline BL, the type of materials and/or stacking order thereof may be varied in example embodiments.

The bitline capping pattern BC may include a first capping pattern 146, a second capping pattern 147, and a third capping pattern 148 stacked in order on the third conductive pattern 143. Each of the first to third capping patterns 146, 147, and 148 may include an insulating material, for example, a silicon nitride film. The first to third capping patterns 146, 147, and 148 may be formed of different materials, and even when the first to third capping patterns 146, 147, and 148 include the same material, a boundary may be distinct due to a difference in physical properties. A thickness of the second capping pattern 147 may be smaller than each of a thickness of the first capping pattern 146 and a thickness of the third capping pattern 148. The number of capping patterns and/or the types of materials forming the bitline capping pattern BC may be varied in example embodiments. The bitline structure BLS may extend perpendicularly to the wordline WL in one direction, for example, the Y-direction. The bitline structure BLS may include a bitline BL and a bitline capping pattern BC on the bitline BL. The bitline structure BLS may be disposed on the cell array region CAR.

The dummy bitline structure BL_D may extend in a direction parallel to the direction in which the bitline structure BLS extends, for example, in the Y-direction. The dummy bitline structure BL_D may be disposed on the connection region IR. The dummy bitline structure BL_D may have a structure similar to the bitline structure BLS, other than the configuration in which the dummy bitline structure BL_D has a greater width in the X-direction than the bitline structure BLS.

The bitline BL may include a first conductive pattern 141, a second conductive pattern 142, and a third conductive pattern 143, stacked in order. The bitline capping pattern BC may be disposed on the third conductive pattern 143. A buffer insulating layer 128 may be disposed between the first conductive pattern 141 and the substrate 101, and one portion of the first conductive pattern 141 (hereinafter, bitline contact pattern DC) may be in contact with the first impurity region 105a of the active region ACT. The bitline BL may be electrically connected to the first impurity region 105a through the bitline contact pattern DC. A lower surface of the bitline contact pattern DC may be positioned at a level lower than a level of an upper surface of the substrate 101 and may be positioned at a level higher than a level of an upper surface of the wordline WL. In example embodiments, the bitline contact pattern DC may be locally disposed in a bitline contact hole 135 formed in the substrate 101 and exposing the first impurity region 105a.

The first conductive pattern 141 may include a semiconductor material such as polycrystalline silicon. The first conductive pattern 141 may be in direct contact with the first impurity region 105a. The second conductive pattern 142 may include a metal-semiconductor compound. The metal-semiconductor compound may be, for example, a layer formed by siliciding a portion of the first conductive pattern 141. For example, the metal-semiconductor compound may include cobalt silicide (CoSi), titanium silicide (TiSi), nickel silicide (NiSi), tungsten silicide (WSi), or other metal silicides. The third conductive pattern 143 may include a metal material, such as titanium (Ti), tantalum (Ta), tungsten (W), or aluminum (Al). The number of conductive patterns included in the bitline BL, the type of material and/or the stacking order thereof may be varied in example embodiments.

The bitline capping pattern BC may include a first capping pattern 146, a second capping pattern 147, and a third capping pattern 148 stacked in order on a third conductive pattern 143. Each of the first to third capping patterns 146, 147, and 148 may include an insulating material, for example, a silicon nitride film. The first to third capping patterns 146, 147, and 148 may be formed of different materials, and even when the first to third capping patterns 146, 147, and 148 include the same material, a boundary may be distinct due to a difference in physical properties. A thickness of the second capping pattern 147 may be smaller than each of a thickness of the first capping pattern 146 and a thickness of the third capping pattern 148. The number of capping patterns and/or the types of materials forming the bitline capping pattern BC may be varied in example embodiments.

The spacer structures SS may be disposed on both sidewalls of each of the bitline structures BLS and may extend in one direction, for example, the Y-direction. The spacer structures SS may be disposed between the bitline structure BLS and the lower conductive pattern 150. The spacer structures SS may be disposed to extend along sidewalls of the bitline BL and sidewalls of the bitline capping pattern BC. A pair of spacer structures SS disposed on both sides of the bitline structure BLS may have an asymmetrical shape with respect to the bitline structure BLS. Each of the spacer structures SS may include a plurality of spacer layers and in example embodiments, each of the spacer structures SS may further include an air spacer. The semiconductor device 100 may further include fence insulating patterns 154 between the spacer structures SS. The fence insulating patterns 154 may include silicon nitride or silicon oxynitride.

The semiconductor device 100 may further include dummy spacer structures SS_D disposed on one side of the dummy bitline structure BL_D and on a side surface of the dummy gate structure GS_D. Each of the dummy spacer structures SS_D may include a plurality of spacer layers, and in example embodiments, each of the dummy spacer structures SS_D may further include an air spacer.

The lower conductive pattern 150 may be connected to one region of the active region ACT, for example, the second impurity region 105b. The lower conductive pattern 150 may be disposed between the bitlines BL and the wordlines WL. The lower conductive pattern 150 may penetrate the buffer insulating layer 128 and may be connected to the second impurity region 105b of the active region ACT. The lower conductive pattern 150 may be in direct contact with the second impurity region 105b. A lower surface of the lower conductive pattern 150 may be positioned at a level lower than an upper surface of the substrate 101 and may be positioned at a level higher than a lower surface of the bitline contact pattern DC. The lower conductive pattern 150 may be insulated from the bitline contact pattern DC by the spacer structure SS. The lower conductive pattern 150 may be formed of a conductive material, and may include at least one of, for example, polycrystalline silicon (Si), titanium (Ti), titanium nitride (TiN), tantalum (Ta), tantalum nitride (TaN), tungsten (W), tungsten nitride (WN), or aluminum (Al). In example embodiments, the lower conductive pattern 150 may include a plurality of layers.

A metal-semiconductor compound layer 155 may be disposed between the lower conductive pattern 150 and the first upper conductive pattern 160c. The metal-semiconductor compound layer 155 may be, for example, formed by siliciding a portion of the lower conductive pattern 150, when the lower conductive pattern 150 includes a semiconductor material. The metal-semiconductor compound layer 155 may include, for example, cobalt silicide (CoSi), titanium silicide (TiSi), nickel silicide (NiSi), tungsten silicide (WSi), or other metal silicides. In example embodiments, the metal-semiconductor compound layer 155 may not be provided.

The first upper conductive pattern 160c may be disposed on the lower conductive pattern 150 in the cell array region CAR. The first upper conductive pattern 160c may extend between the spacer structures SS and may cover an upper surface of the metal-semiconductor compound layer 155. The second and third upper conductive patterns 160p1 and 160p2 may be disposed on the connection region IR and the peripheral circuit region PCR. The upper surfaces of the first to third upper conductive patterns 160c, 160p1 and 160p2 may be disposed at substantially the same level. Each of the upper conductive patterns 160c, 160p1 and 160p2 may include a barrier layer 162 and a conductive layer 164. The barrier layer 162 may cover a lower surface and side surfaces of the conductive layer 164. The barrier layer 162 may include at least one of a metal nitride, for example, titanium nitride (TiN), tantalum nitride (TaN), or tungsten nitride (WN). The conductive layer 164 may include at least one of a conductive material, for example, polycrystalline silicon (Si), titanium (Ti), tantalum (Ta), tungsten (W), ruthenium (Ru), copper (Cu), molybdenum (Mo), platinum (Pt), nickel (Ni), cobalt (Co), aluminum (Al), titanium nitride (TiN), tantalum nitride (TaN), or tungsten nitride (WN).

The contact plug 160cp1 may be connected to an end portion EP of the wordline WL. The contact plug 160cp1 may be provided in the connection region IR. An end portion EP of the wordline WL may provide an end surface ES exposed in the extension direction of the wordline WL, that is, the first direction X, and the contact plug 160cp1 may be disposed to overlap the end portion EP of the wordline WL in the vertical direction Z.

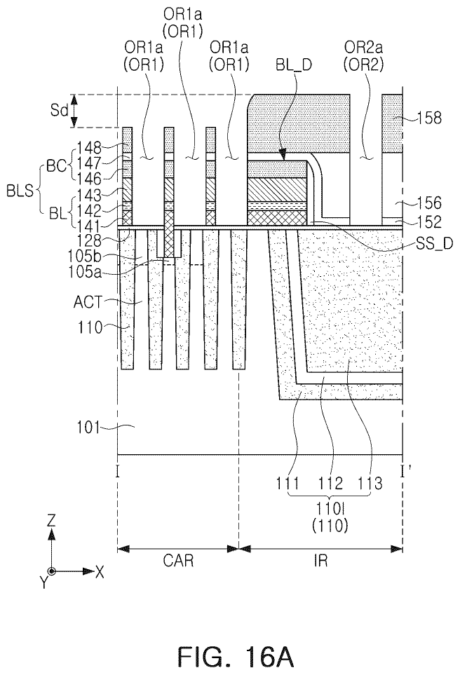

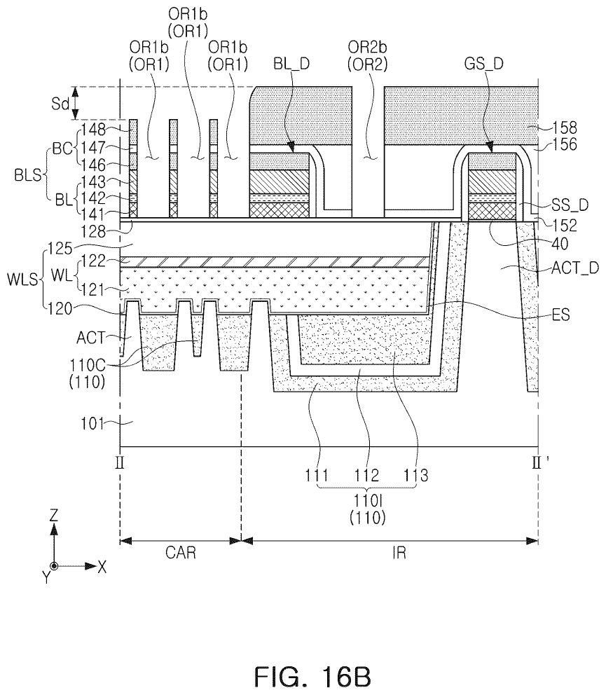

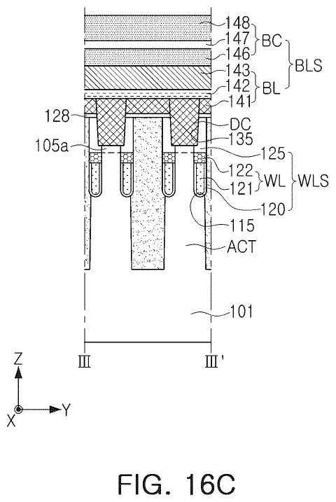

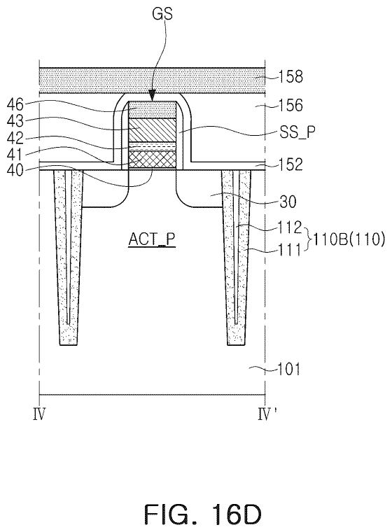

The dummy structures DS may penetrate at least a portion of the insulating structures 152, 156, and 158 on the connection region IR. For example, the dummy structures DS may be formed in the open region (‘OR2a’ in FIG. 16A and ‘OR2b’ in FIG. 16B) penetrating the insulating structures 152, 156, and 158. The dummy structures DS may include first dummy structures DS1 disposed between wordline structures WLS adjacent to one another and second dummy structures DS2 vertically overlapping the wordline structure WLS. In another aspect, the first dummy structure DS1 may be defined as a dummy structure not vertically overlapping the wordline structure WLS. The dummy structures DS may be spaced apart from one another in the Y-direction, and each of the dummy structures DS may be aligned in the Y-direction.

A distance d1 between the first dummy structure DS1 and the second dummy structure DS2, most adjacent to one another in the Y-direction, may be greater than or substantially the same as a distance d2 between the bitline structures BL, adjacent to one another in the X-direction.

The first dummy structure DS1 may penetrate interlayer insulating layers 156 and 158 and an insulating liner 152 on one side of the dummy bitline structure BL_D. An upper surface of the first dummy structure DS1 may be at substantially the same level as an upper surface of the interlayer insulating layer 158. An upper surface of the first dummy structure DS1 may be at a level higher than a level of an upper surface of the dummy bitline structure BL_D. A lower surface of the first dummy structure DS1 may be at a level lower than a level of a lower surface of the dummy bitline structure BL_D. At least a portion of the first dummy structure DS1 may penetrate a buffer insulating layer 128 and a connection device isolation region 110I.

The first dummy structure DS1 may further include a first dummy spacer structure SS′ disposed on a sidewall of the open region (‘OR2a’ in FIG. 16A) and dummy conductive patterns 150′, 155′, and 164′ filling the other portion of the open region. The dummy conductive patterns 150′, 155′, and 164′ may include a lower dummy conductive pattern 150′ of which at least a portion penetrates the connection device isolation region 110I and the other portion is surrounded by the first dummy spacer structure SS′, a dummy metal-semiconductor compound layer 155′ on the lower dummy conductive pattern 150′, and a dummy conductive layer 164′ on the dummy metal-semiconductor compound layer 155′. In another aspect, the first dummy spacer structure SS′ may surround sidewalls of the dummy conductive patterns 150′, 155′, and 164′. A lower surface of the lower dummy conductive pattern 150′ may be at a level lower than a level of a lower surface of the dummy bitline structure BL_D.

The first dummy structure DS1 may further include a barrier layer 162′ disposed between the first dummy spacer structure SS′ and the dummy conductive layer 164′. The barrier layer 162′ may cover the upper surface of the dummy metal-semiconductor compound layer 155′.

At least one of the first dummy spacer structures SS′ on the connection region IR and the spacer structures SS on the cell array region CAR may be at substantially the same level. At least one of the first dummy spacer structures SS′ and the spacer structures SS may include substantially the same material.

The lower dummy conductive pattern 150′ on the connection region IR and the lower conductive pattern 150 on the cell array region CAR may be at substantially the same level. The lower dummy conductive pattern 150′ and the lower conductive pattern 150 may include substantially the same material.

The dummy metal-semiconductor compound layer 155′ on the connection region IR and the metal-semiconductor compound layer 155 on the cell array region CAR may be at substantially the same level. The dummy metal-semiconductor compound layer 155′ and the metal-semiconductor compound layer 155 may include substantially the same material.

The dummy conductive layer 164′ on the connection region IR and the conductive layer 164 on the cell array region CAR may be at substantially the same level. The dummy conductive layer 164′ and the conductive layer 164 may include substantially the same material.

The semiconductor device 100 may further include an interlayer insulating layer 159 disposed on the interlayer insulating layers 156 and 158 in the connection region IR and the peripheral circuit region PCR. The interlayer insulating layer 159 may be disposed on an upper portion of the first dummy structure DS1.

The second dummy structure DS2 may be aligned with the first dummy structure DS1 in the Y-direction. The second dummy structure DS2 may penetrate the interlayer insulating layers 156 and 158 and the insulating liner 152 between the dummy bitline structure BL_D and the contact plug 160cp1. An upper surface of the second dummy structure DS2 may be substantially at the same level as an upper surface of the interlayer insulating layer 158. An upper surface of the second dummy structure DS2 may be at a level higher than a level of an upper surface of the dummy bitline structure BL_D. A lower surface of the second dummy structure DS2 may be substantially at the same level as a lower surface of the dummy bitline structure BL_D.

The second dummy structure DS2 may further include a second dummy spacer structure SS″ disposed on a sidewall of the open region (‘OR2b’ in FIG. 16B) and a dummy insulating pattern 154′ filling the other portion of the open region. In another aspect, the second dummy spacer structure SS″ may surround a sidewall of the dummy insulating pattern 154′.

The second dummy spacer structure SS″ on the connection region IR may be at a level higher than a level of the spacer structures SS on the cell array region CAR. For example, the upper surface of the second dummy spacer structure SS″ may be at a level higher than a level of the upper surface of the spacer structures SS. The second dummy spacer structure SS″ and at least one of the spacer structures SS may include substantially the same material.

The dummy insulating pattern 154′ on the connection region IR may be at a level higher than a level of the fence insulating pattern 154 on the cell array region CAR. For example, the upper surface of the dummy insulating pattern 154′ may be at a level higher than a level of the upper surface of the fence insulating pattern 154. The lower surfaces of each of the dummy insulating pattern 154′ and the fence insulating pattern 154 may be substantially at the same level. The dummy insulating pattern 154′ and the fence insulating pattern 154 may include substantially the same material.

At least a portion of the first dummy structure DS1 and at least a portion of the second dummy structure DS2 may be substantially at the same level. For example, the upper surface of the first dummy structure DS1 and the upper surface of the second dummy structure DS2 may be substantially at the same level. The lower surface of the first dummy structure DS1 and the lower surface of the second dummy structure DS2 may be substantially at the same level.

In planar view, the first and second dummy structures DS1 and DS2 may have a quadrangular shape, but example embodiments thereof is not limited thereto. For example, in planar view, at least one of the first dummy structures DS1 and/or at least one of the second dummy structures DS2 may have a polygonal shape including a triangular shape, a pentagonal shape, or the like.

The peripheral contact plug 160cp2 may penetrate the first and second interlayer insulating layers 156 and 158 and the insulating liner 152 in the peripheral circuit region PCR and may be connected to the peripheral source/drain regions 30. A peripheral metal-semiconductor compound layer 35 may be disposed between the peripheral contact plug 160cp2 and the peripheral source/drain regions 30. The peripheral contact plug 160cp2 may be connected to the third upper conductive pattern 160p2 and may be integrated with the third upper conductive pattern 160p2.

The insulating patterns 165 may be disposed to penetrate the upper conductive patterns 160c, 160p1, and 160p2. The upper conductive patterns 160c, 160p1, and 160p2 may be divided into a plurality by the insulating patterns 165. The insulating patterns 165 may include at least one of an insulating material, for example, silicon oxide, silicon nitride, or silicon oxynitride.

A peripheral gate structure GS may be disposed on a peripheral active region ACT_P in a peripheral circuit region PCR. The peripheral gate structure GS may include a peripheral gate dielectric layer 40, peripheral gate electrodes 41, 42, and 43, and a peripheral gate capping layer 46, stacked in order. An insulating liner 152 may cover the peripheral gate structure GS. The peripheral active region ACT_P may be defined by a peripheral device isolation region 110B, and the peripheral device isolation region 110B may include a first insulating liner 111 and a second insulating liner 112 including different materials, but example embodiments thereof is not limited thereto. The peripheral gate dielectric layer 40 may include silicon oxide, silicon nitride, or a high-κ material. The high-κ material may indicate a dielectric material having a dielectric constant higher than that of silicon oxide. The peripheral gate electrodes 41, 42, and 43 may have a structure similar to that of the bitline BL and may be formed of a material similar to that of the bitline BL, and may have a shape having a width greater than that of the bitline BL.

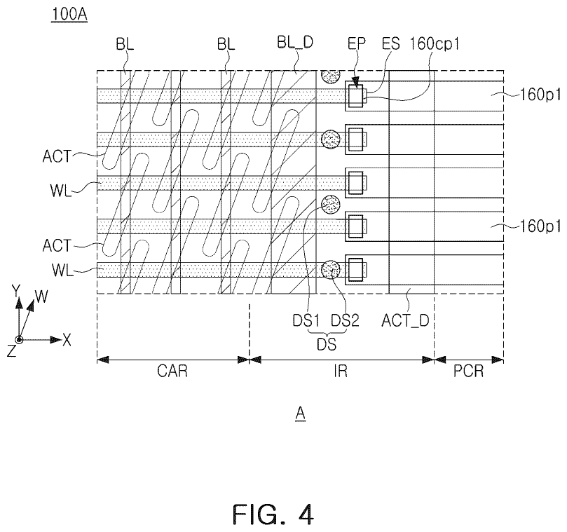

FIG. 4 is a plan diagram illustrating a semiconductor device 100A according to example embodiments.

Referring to FIG. 4, the semiconductor device 100A may be configured the same or similar to the example described with reference to FIGS. 1, 2A, 2B, 3A, 3B, 3C, and 3D, other than the configuration in which first and second dummy structures DS1 and DS2 having at least one circular shape in a planar view are included.

As described above, the shapes of the first and second dummy structures DS1 and DS2 in a planar view may not be limited to a quadrangular shape. For example, the shapes may include a polygonal shape including a triangular shape, a pentagonal shape, or the like, an elliptic shape, and a circular shape.

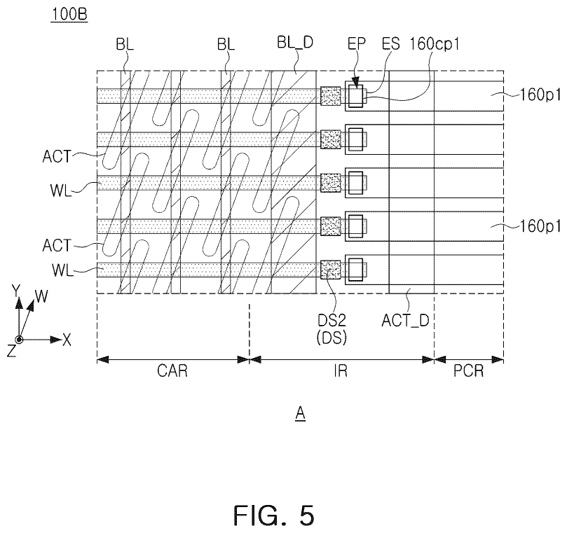

FIG. 5 is a plan diagram illustrating a semiconductor device 100B according to example embodiments.

Referring to FIG. 5, the semiconductor device 100B may be configured the same as or similar to the example described with reference to FIGS. 1, 2A, 2B, 3A, 3B, 3C, 3D, and 4, other than the configuration in which dummy structures DS limitedly includes the first dummy structures DS1 or the second dummy structures DS2 described with reference to FIGS. 1, 2A, 2B, 3A, 3B, 3C, 3D, and 4.

For example, the semiconductor device 100B may limitedly include dummy structures (e.g., DS2) vertically overlapping the wordline structure WLS, or may limitedly include dummy structures (e.g., DS1) disposed between the wordline structures WLS.

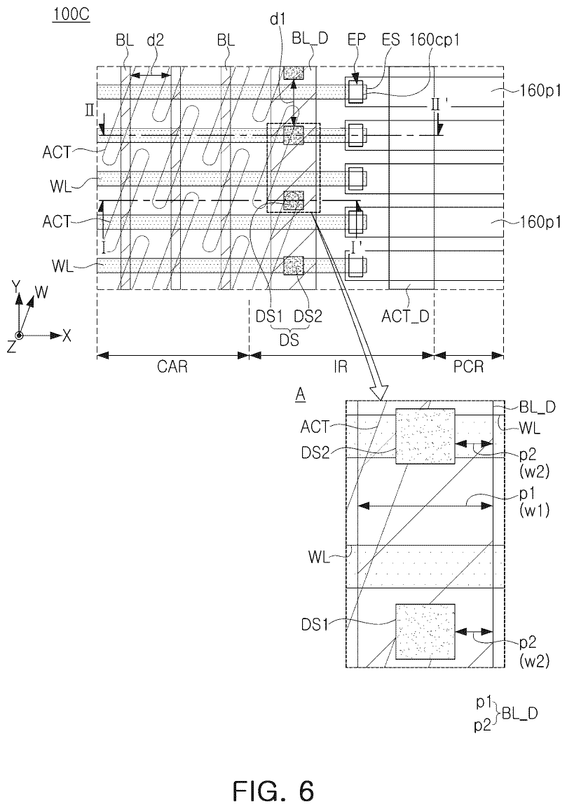

FIG. 6 is a plan diagram illustrating a semiconductor device 100C according to example embodiments.

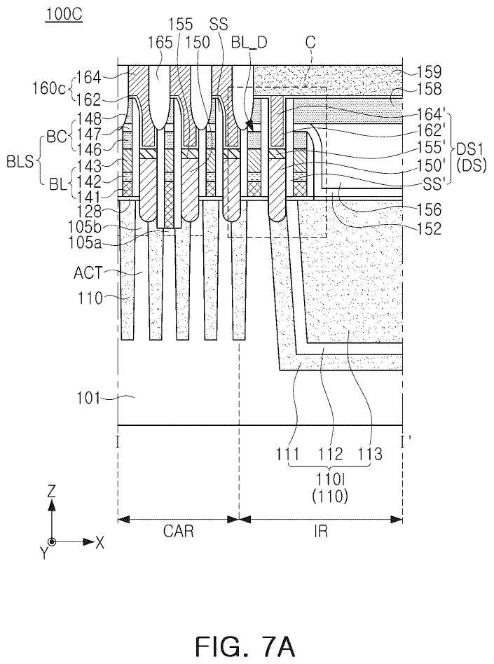

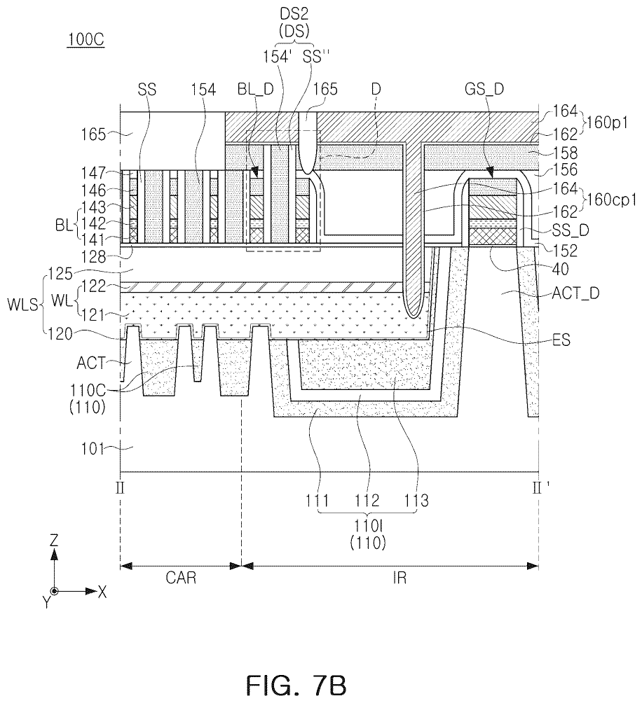

FIGS. 7A and 7B are cross-sectional diagrams illustrating a semiconductor device according to example embodiments. FIG. 7A is a cross-sectional diagram taken along line I-I′ in FIG. 6. FIG. 7B is a cross-sectional diagram taken along line II-II′ in FIG. 6.

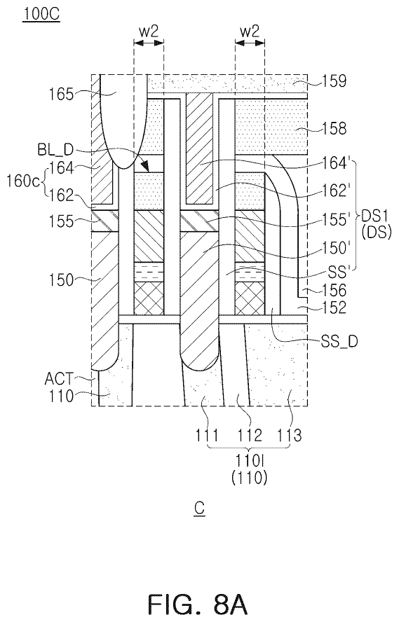

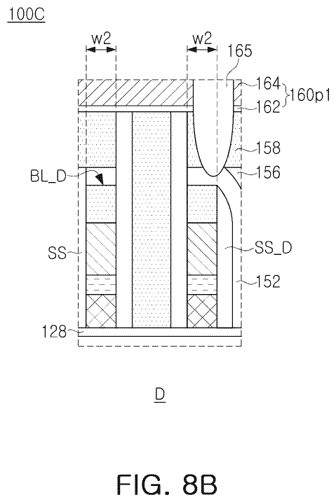

FIGS. 8A and 8B are enlarged diagrams illustrating a portion of a semiconductor device according to example embodiments. FIG. 8A is an enlarged diagram illustrating region “C” in FIG. 7A. FIG. 8B is an enlarged diagram illustrating region “D” in FIG. 7B.

Referring to FIGS. 6, 7A, 7B, 8A, and 8B, example embodiments may be the same as or similar to the example described with reference to FIGS. 1 to 5, other than the configuration in which the dummy structures DS are formed on the dummy bitline structure BL_D.

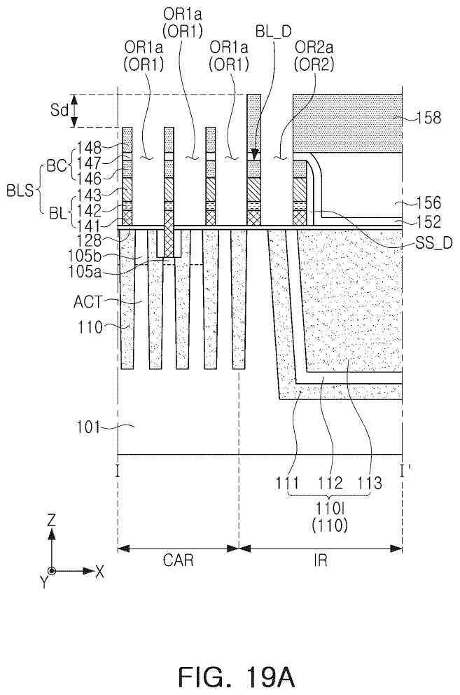

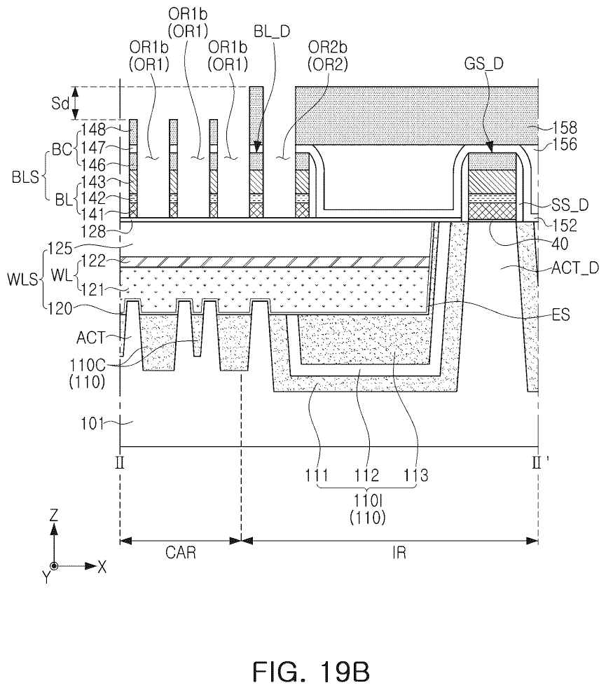

The dummy structures DS may penetrate the dummy bitline structure BL_D on the connection region IR. For example, the dummy structures DS may be formed in the open region (‘OR2a’ in FIG. 19A and ‘OR2b’ in FIG. 19B) penetrating the interlayer insulating layer 158, the insulating liner 152, and the dummy bitline structure BL_D.

The first dummy structure DS1 may penetrate the interlayer insulating layer 158, the insulating liner 152, the dummy bitline structure BL_D, and the connection device isolation region 110I between the wordline structures WLS adjacent to one another.

An upper portion region of the first dummy spacer structure SS′ may be in contact with a side surface of the interlayer insulating layer 158 and the insulating liner 152 defined by the open region (‘OR2a’ in FIG. 19A). A lower region of the first dummy spacer structure SS′ may be in contact with a side surface of the dummy bitline structure BL_D defined by the open region (‘OR2a’ in FIG. 19A). A lower region of the lower dummy conductive pattern 150′ may be in contact with the connection device isolation region 110I.

The second dummy structure DS2 may penetrate the interlayer insulating layer 158, the insulating liner 152 and the dummy bitline structure BL_D on the wordline structure WLS. An upper portion region of the second dummy spacer structure SS″ may be in contact with the side surfaces of the interlayer insulating layer 158 and the insulating liner 152 defined by the open region (‘OR2b’ in FIG. 19B), and a lower region of the second dummy spacer structure SS″ may be in contact with the side surface of the dummy bitline structure BL_D defined by the open region (‘OR2b’ in FIG. 19B).

By the dummy structures DS, dummy bitline structure BL_D may have different widths in the first direction X. The dummy bitline structure BL_D may include a first portion p1 having a first width w1 and a second portion p2 having a second width w2 smaller than the first width w1.

The first portion p1 may include a portion of the dummy bitline structure BL_D not penetrated by the dummy structures DS in the first direction X.

The second portion p2 may include a portion of the dummy bitline structure BL_D penetrated by the dummy structures DS in the first direction X. In another aspect, the second width w2 may be defined as a width of the dummy bitline structure BL_D on one side of the dummy structures DS in the first direction X.

For ease of description, the first and second portions p1 and p2 may be provided to describe dummy bitline structures BL_D having different widths. Accordingly, a boundary between the first and second portions p1 and p2 may not be particularly distinct, and the first and second portions p1 and p2 may be consecutive.

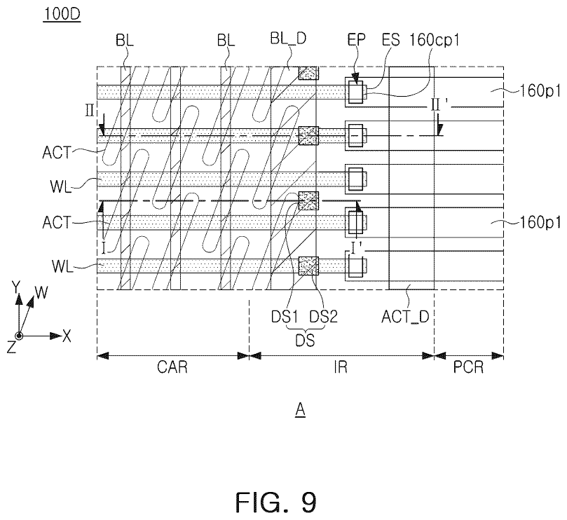

FIG. 9 is a plan diagram illustrating a semiconductor device according to example embodiments.

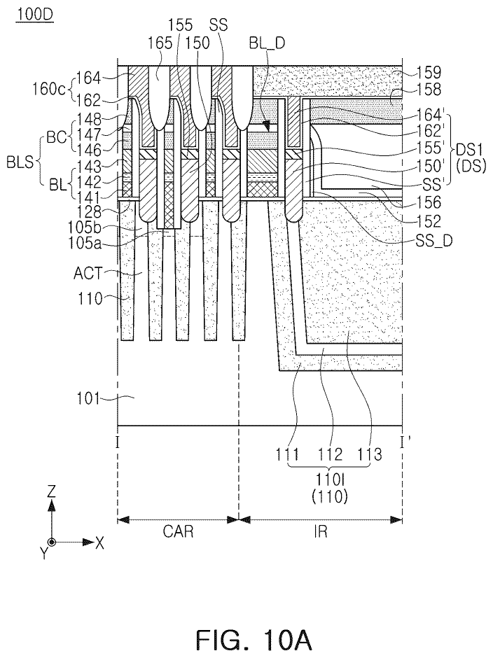

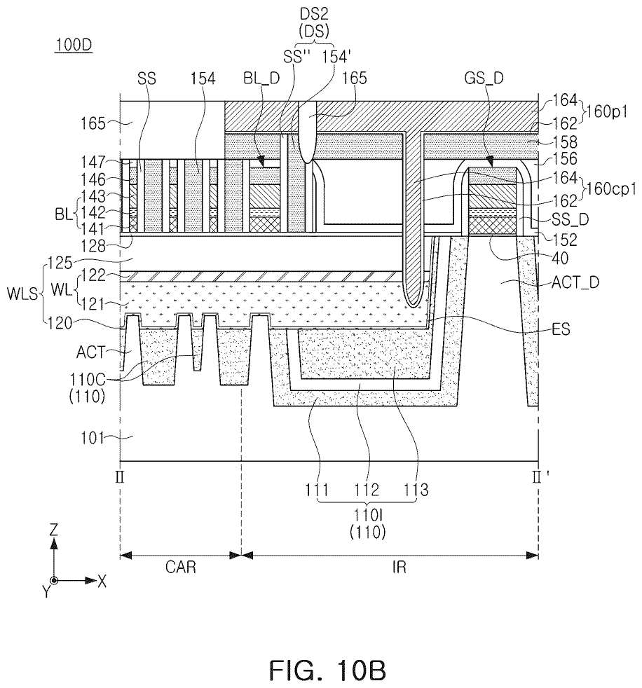

FIGS. 10A and 10B are cross-sectional diagrams illustrating a semiconductor device according to example embodiments. FIG. 10A is a cross-sectional diagram taken along line I-I′ in FIG. 9. FIG. 10B is a cross-sectional diagram taken along line II-II′ in FIG. 9.

Referring to FIGS. 9, 10A, and 10B, example embodiments may be the same as or similar to the example described with reference to FIGS. 1, 2A, 2B, 3A, 3B, 3C, 3D, 4, 5, 6, 7A, 7B, 8A, and 8B, other than the configuration in which the dummy structures DS penetrate at least a portion of the dummy spacer structure SS_D on the sidewall of the dummy bitline structure BL_D.

The first dummy structure DS1 may penetrate an interlayer insulating layer 158, an insulating liner 152, a dummy spacer structure SS_D and the dummy bitline structure BL_D between the wordline structures WLS adjacent to one another. In example embodiments, the first dummy structure DS1 may be in contact with the dummy spacer structure SS_D. For example, the first dummy spacer structure SS′ and the dummy spacer structure SS_D may be in contact with one another.

The second dummy structure DS2 may penetrate the interlayer insulating layer 158, the insulating liner 152, the dummy spacer structure SS_D and the dummy bitline structure BL_D on the wordline structure WLS. In example embodiments, the second dummy structure DS2 may be in contact with the dummy spacer structure SS_D. For example, the second dummy spacer structure SS″ and the dummy spacer structure SS_D may be in contact with one another.

At least one of the insulating patterns 165 may penetrate at least a portion of the second dummy structure DS2. For example, at least one of the insulating patterns 165 may penetrate an upper portion region of the second dummy spacer structure SS″ and the dummy insulating pattern 154′.

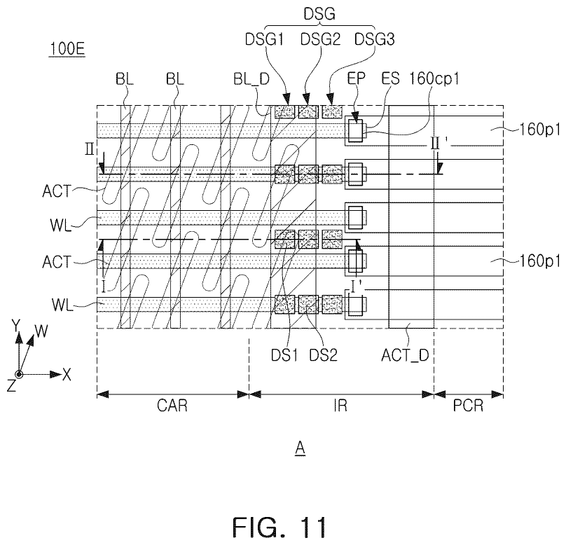

FIG. 11 is a plan diagram illustrating a semiconductor device 100E according to example embodiments.

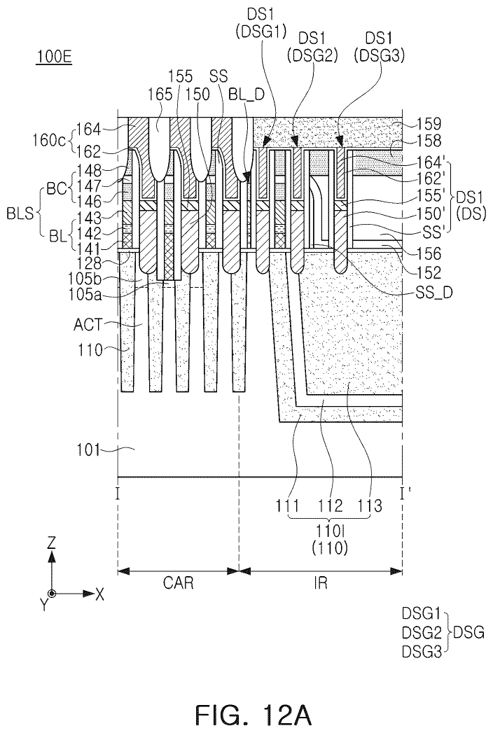

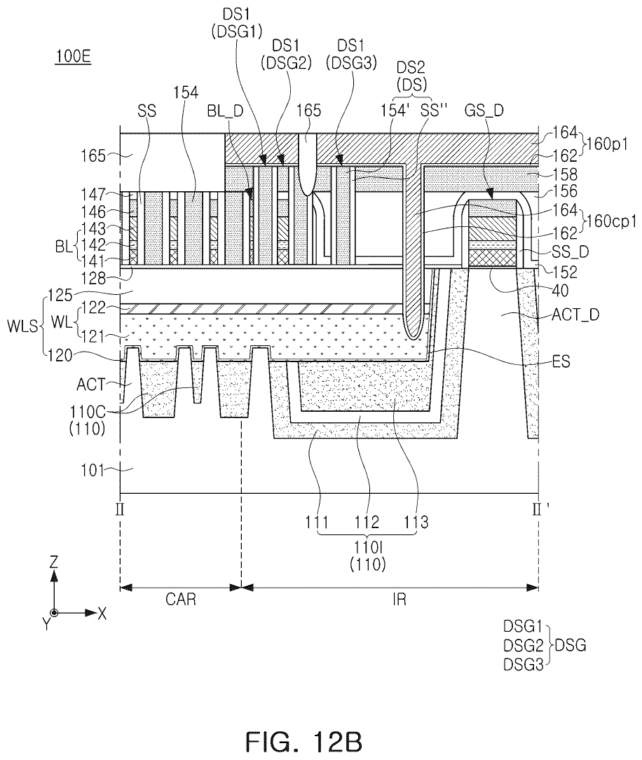

FIGS. 12A and 12B are cross-sectional diagrams illustrating a semiconductor device according to example embodiments. FIG. 12A is a cross-sectional diagram taken along line I-I′ in FIG. 11. FIG. 12B is a cross-sectional diagram taken along line II-II′ in FIG. 11.

Referring to FIGS. 11, 12A, and 12B, the semiconductor device 100E may include a plurality of dummy structure groups DSG spaced apart from one another in the first direction X.

The plurality of dummy structure groups DSG may include first to third dummy structure groups DSG1, DSG2, and DSG3.

Each of the first to third dummy structure groups DSG1, DSG2, and DSG3 may include first and second dummy structures DS1 and DS2 described with reference to FIGS. 1, 2A, 2B, 3A, 3B, 3C, 3D, 4, 5, 6, 7A, 7B, 8A, 8B, 9, 10A, and 10B. The first to third dummy structure groups DSG1, DSG2, and DSG3 may be spaced apart from one another in the first direction X in the connection region IR.

At least a portion of the plurality of dummy structure groups DSG may vertically overlap the dummy bitline structure BL_D. A portion of the plurality of dummy structure groups DSG may be spaced apart from the dummy bitline structure BL_D. In another aspect, the portion of the plurality of dummy structure groups DSG may not vertically overlap the dummy bitline structure BL_D.

For example, the first dummy structure group DSG1 may be formed on the dummy bitline structure BL_D, similarly to the dummy structures DS described with reference to FIGS. 6, 7A, 7B, 8A, and 8B.

The second dummy structure group DSG2 may penetrate at least a portion of the dummy spacer structure SS_D on a sidewall of the dummy bitline structure BL_D, similarly to the dummy structures DS described with reference to FIGS. 9, 10A, and 10B.

At least a portion of the third dummy structure group DSG3 may penetrate the insulating structures 152, 156 and 158 and the connection device isolation region 110I on one side of the dummy bitline structure BL_D, similarly to the first dummy structures DS1 described with reference to FIGS. 1, 2A, 2B, 3A, 3B, 3C, and 3D.

A portion of the third dummy structure group DSG3 may penetrate the insulating structures 152, 156, and 158 between the dummy bitline structure BL_D and the contact plug 160cp1, similarly to the second dummy structures DS2 described with reference to FIGS. 1, 2A, 2B, 3A, 3B, 3C, and 3D.

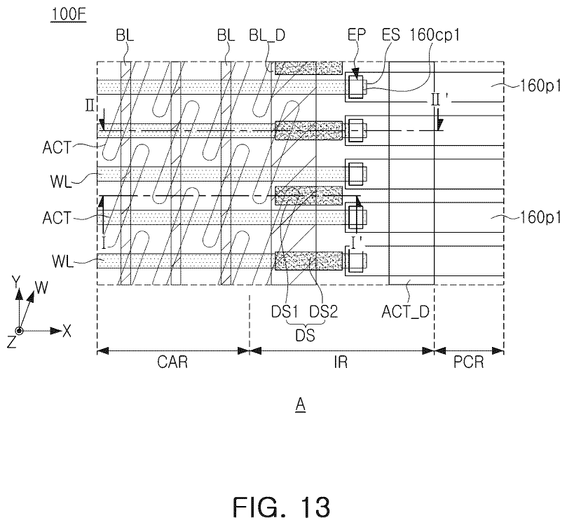

FIG. 13 is a plan diagram illustrating a semiconductor device according to example embodiments.

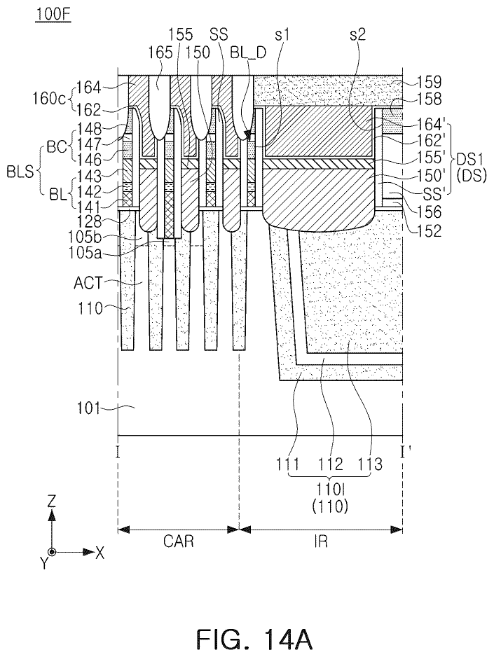

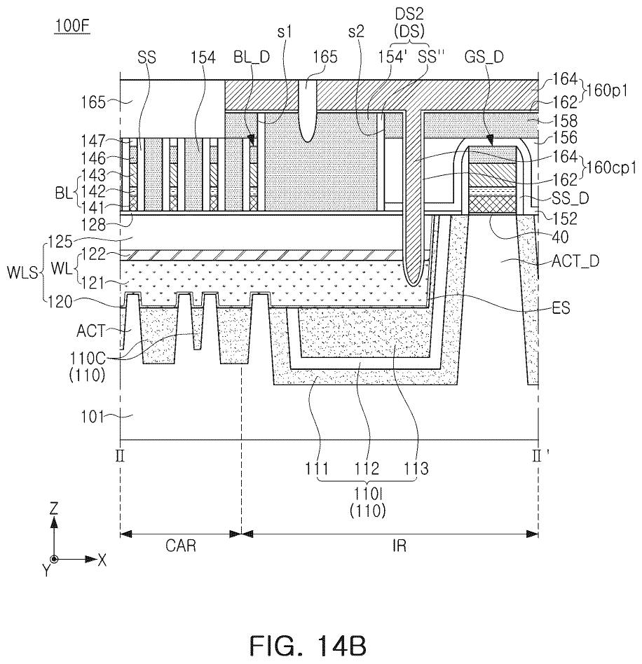

FIGS. 14A and 14B are cross-sectional diagrams illustrating a semiconductor device according to example embodiments. FIG. 14A is a cross-sectional diagram taken along line I-I′ in FIG. 13. FIG. 14B is a cross-sectional diagram taken along line II-II′ in FIG. 13.

Referring to FIGS. 13, 14A, and 14B, a semiconductor device 100F may be configured the same as or similar to the example described with reference to FIGS. 1 to 12B, other than the configuration in which dummy structures DS having a width greater than the width in the first direction X of the dummy bitline structure BL_D are included.

The first dummy structure DS1 may penetrate the interlayer insulating layers 156 and 158, the insulating liner 152 and the dummy bitline structure BL_D between the wordline structures WLS adjacent to one another.

In example embodiments, both side surfaces s1 and s2 of the first dummy structure DS1, opposing one another in the first direction X, may be defined in different regions. The first side s1 may be defined on the dummy bitline structure BL_D, and the second side s2 may be defined on the insulating structure 152, 156, and 158 beyond the dummy bitline structure BL_D. The first side may be directed to the bitline structure BLS, and the second side s2 may be directed to the dummy gate structure GS_D.

In example embodiments, widths of the dummy conductive patterns 150′, 155′, and 164′ on the connection region IR may be greater than widths of the conductive patterns 150, 155, and 164 on the cell array region CAR, respectively.

The second dummy structure DS2 may penetrate the interlayer insulating layers 156 and 158, the insulating liner 152, and the dummy bitline structure BL_D on the wordline structure WLS.

In example embodiments, a first side of the second dummy structure DS2 may be defined on the dummy bitline structure BL_D, and a second side opposite to the first side may be defined on the insulating structure 152, 156, and 158 beyond the dummy bitline structure BL_D. The first side may be adjacent to the bitline structure BLS, and the second side may be adjacent to the contact plug 160cp1. The first side of the first dummy structure DS1 and the first side of the second dummy structure DS2 may be aligned, and the second side of the first dummy structure DS1 and the second side of the second dummy structure DS2 may be aligned.

In example embodiments, a width of the dummy insulating pattern 154′ on the connection region IR may be greater than a width of the fence insulating pattern 154 on the cell array region CAR.

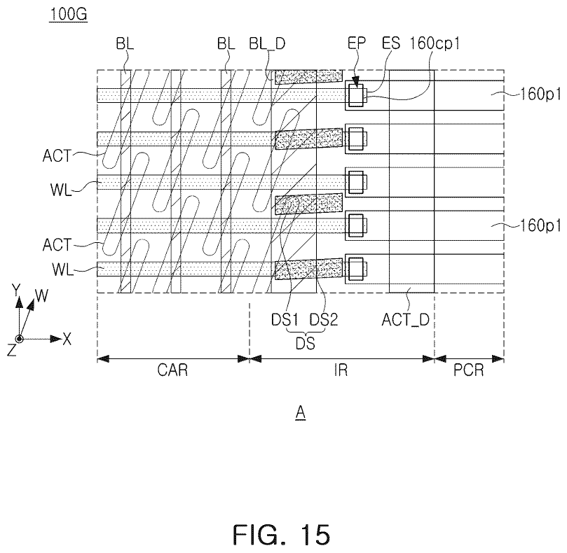

FIG. 15 is a plan diagram illustrating a semiconductor device 100G according to example embodiments.

Referring to FIG. 15, the semiconductor device 100G may be configured the same as or similar to the example described with reference to FIGS. 1, 2A, 2B, 3A, 3B, 3C, 3D, 4, 5, 6, 7A, 7B, 8A, 8B, 9, 10A, 10B, 11, 12A, 12B, 13, 14A, and 14B, other than the configuration in which dummy structures DS extending in the diagonal direction is included.

As compared to the dummy structures DS of the semiconductor device 100F in FIGS. 13, 14A and 14B, at least one of the dummy structures DS of the semiconductor device 100G in FIG. 15 may have a structure extending in the diagonal direction.

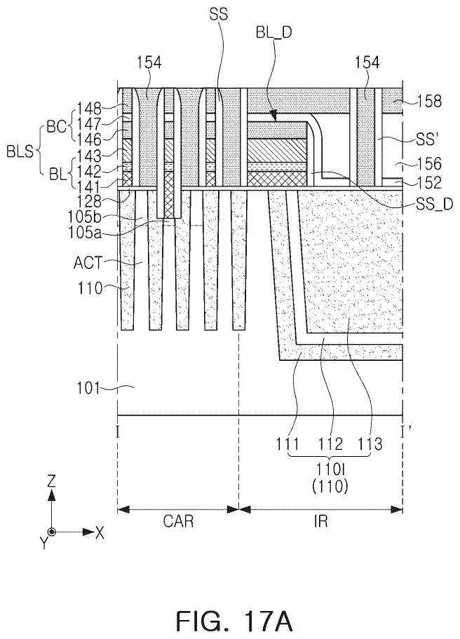

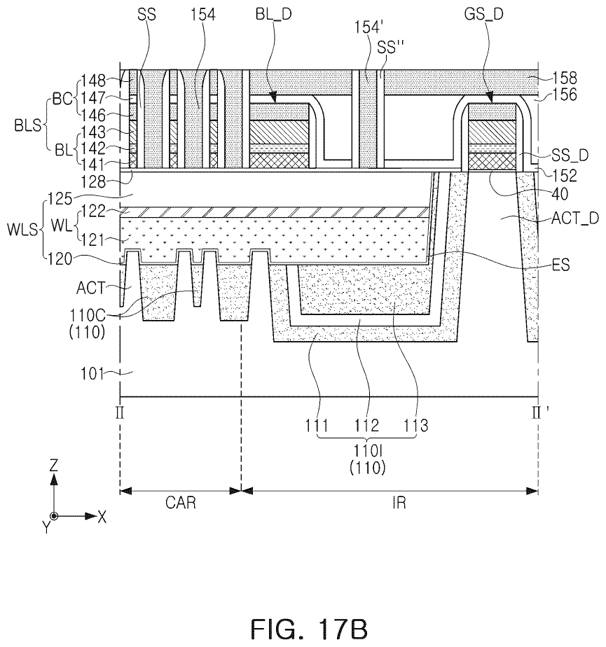

FIGS. 16A, 16B, 16C, 16D, FIGS. 17A and 17B, and FIGS. 18A, 18B, 18C, and 18D are cross-sectional diagrams illustrating processes of a method of manufacturing a semiconductor device in order according to example embodiments.

Referring to FIGS. 1, 2A, 2B, 16A, 16B, 16C, and 16D, by forming a device isolation region 110 on a substrate 101, a cell active region ACT may be defined in a cell array region CAR, a dummy active region ACT_D may be defined in a connection region IR, and a peripheral active region ACT_P may be defined in a peripheral circuit region PCR. A device isolation trench may be formed on the substrate 101, and the device isolation region 110 may fill the device isolation trench. In planar view, the active region ACT may have a bar shape elongated in the W direction. An ion implantation process may be performed using the device isolation region 110 as an ion implantation mask, thereby forming impurity regions on an upper portion of the active region ACT. A gate trench 115 may be formed by patterning the active region ACT and the device isolation region 110. A pair of gate trenches 115 may cross the active region ACT, but example embodiments thereof is not limited thereto. The impurity regions may also be isolated by the gate trench 115, and a first impurity region 105a and a second impurity region 105b may be formed.

A gate dielectric layer 120 may be formed on an internal surface of the gate trench 115 with a substantially conformal thickness. Thereafter, a lower pattern 121 and an upper pattern 122 may be formed to fill the gate trench 115, and a wordline WL may be formed by partially etching an upper portion of the upper pattern 122. An upper surface of the wordline WL may be recessed to be at a level lower than an upper surface of the active region ACT. The gate trench 115 may be filled by stacking an insulating layer on the substrate 101, and may be etched, thereby forming a gate capping layer 125 on the wordline WL.

An insulating layer and a conductive layer may be formed in order on the entire surface of the substrate 101 and may be patterned, thereby forming a buffer insulating layer 128 and a first conductive pattern 141 stacked in order. The buffer insulating layer 128 may be formed of at least one of silicon oxide, silicon nitride, or silicon oxynitride. A plurality of the buffer insulating layers 128 may be spaced apart from one another. The first conductive pattern 141 may have a shape corresponding to a planar shape of the buffer insulating layer 128. The buffer insulating layer 128 may be formed to simultaneously cover the ends of two neighboring active regions ACT, that is, neighboring second impurity regions 105b. An upper portion of the device isolation region 110, the substrate 101, and the gate capping layer 125 may be etched using the buffer insulating layer 128 and the first conductive pattern 141 as etching masks, thereby forming a bitline contact hole 135. The bitline contact hole 135 may expose the first impurity region 105a.

A bitline contact pattern DC filling the bitline contact hole 135 may be formed. The forming the bitline contact pattern DC may include forming a conductive layer filling the bitline contact hole 135 and performing a planarization process. For example, the bitline contact pattern DC may be formed of polysilicon. A second conductive pattern 142, a third conductive pattern 143, and first to third capping patterns 146, 147, and 148 may be formed in order on the first conductive pattern 141.

Peripheral transistors may be formed in the peripheral circuit region PCR. The peripheral transistors may include a peripheral gate structure GS and peripheral source/drain regions 30. A peripheral gate spacer structure SS_P may be formed on a side surface of the peripheral gate structure GS. The peripheral gate structure GS may be formed in the same process as the forming the bitline BL, but example embodiments thereof is not limited thereto. An insulating liner 152, a first interlayer insulating layer 156, and a second interlayer insulating layer 158 covering the peripheral transistors may be formed. Each of the insulating liner 152, the first interlayer insulating layer 156, and the second interlayer insulating layer 158 may include at least one of silicon oxide, silicon nitride, or silicon oxynitride.

The first to third conductive patterns 141, 142, and 143 may be etched in order using the first to third capping patterns 146, 147, and 148 as an etching mask sing an etching process. Accordingly, the first open regions OR1 may be formed.

Each of the first open regions OR1 may extend in the second direction Y, and the first open regions OR1 may be spaced apart from one another in the first direction X.

The first open regions OR1 may define a side surface of the bitline structure BLS. The bitline structure BLS may include a bitline BL including the first to third conductive patterns 141, 142, and 143 and a bitline capping pattern BC including the first to third capping patterns 146, 147, and 148.

The first open regions OR1 may include 1-1 open regions OR1a between the wordline structures WL (see FIG. 16A). The first open regions OR1 may include 1-2 open regions OR1b vertically overlapping each of the wordline structures WL (see FIG. 16B).

In the connection region IR, a dummy bitline structure BL_D (or, dummy bitline) may be formed.

After performing the etching process, an upper surface level of the third capping pattern 148 and the second interlayer insulating layer 158 may be different from one another. From a different perspective, the preliminary semiconductor device having undergone the etching process may have a step difference Sd between the cell array region CAR and the connection region IR. The step difference Sd may be due to the plurality of first open regions OR1 formed on the cell array region CAR. The step difference Sd may have a negative effect on the precision and flatness of the subsequent process, which may reduce reliability of the semiconductor device formed ultimately.

According to example embodiments, the etching process may further include etching the first and second interlayer insulating layers 156 and 158 and forming second open regions OR2. Accordingly, the process environment difference formed between the cell array region CAR and the connection region IR due to the step difference Sd may be alleviated, and similar process conditions between the two regions may be created. In example embodiments, the first and second open regions OR1 and OR2 may be collectively referred to as a plurality of open regions. The first and second open regions OR1 and OR2 may be formed through the same process, that is, the same etching process.

The second open regions OR2 may penetrate the insulating liner 152, the first interlayer insulating layer 156, and the second interlayer insulating layer 158. The second open regions OR2 may include 2-1 open regions OR2a between the wordline structures WL (see FIG. 16A). The second open regions OR2 may include 2-2 open regions OR2b vertically overlapping the wordline structures WL (see FIG. 16B). The second open regions OR2 may be spaced apart from and aligned in the second direction Y.

Referring to FIGS. 1, 2A, 2B, 17A and 17B, a spacer structure SS and a fence insulating pattern 154 may be formed in first and second open regions OR1 and OR2. Accordingly, a second dummy structure DS2 may be defined.

The spacer structure SS may be formed on side surfaces of bitline structure BLS defined by the first open region OR1. The spacer structure SS may also be formed in the second open region OR2. The spacer structure SS may include a plurality of layers.

Fence insulating patterns 154 may be formed between the spacer structures SS. The fence insulating patterns 154 may include silicon nitride or silicon oxynitride. The fence insulating patterns 154 may also be formed in the second open region OR2, and in this case, for ease of description, the fence insulating patterns 154 may be referred to as dummy insulating pattern 154′.

The spacer structure SS and the dummy insulating pattern 154′ formed in the 2-2 open region OR2b among the second open regions OR2 may be defined as the second dummy structure DS2.

Thereafter, a flattening process of removing the step difference (‘Sd’ in FIGS. 16A and 16B) may be optionally performed.

Referring to FIGS. 1, 2A, 2B, 18A, 18B, 18C, and 18D, by performing an anisotropic etching process using the fence insulating patterns 154 and the third capping pattern 148 as etching masks, a first opening OP1 exposing a second impurity region 105b may be formed. The anisotropic etching process may include forming a second opening OP2 exposing a connection device isolation region 110I using the dummy insulating pattern 154′ as an etching mask.

The first and second openings OP1 and OP2 may be formed between the wordline structures WLS. In another aspect, the first opening OP1 may correspond to the 1-1 open region OR1a, and the second opening OP2 may correspond to the 2-1 open region OR2a.

A conductive material may be formed on a lower portion of each of the first and second openings OP1 and OP2. A lower conductive pattern 150 may be formed on the lower portion of the first openings OP1, and a lower dummy conductive pattern 150′ may be formed on the lower portion of the second opening OP2.

A metal-semiconductor compound may be formed on the conductive material. A metal-semiconductor compound layer 155 may be formed on the lower conductive pattern 150, and a dummy metal-semiconductor compound layer 155′ may be formed on the lower dummy conductive pattern 150′.

A first contact hole Ha penetrating the first and second interlayer insulating layers 156 and 158, the insulating liner 152, and the buffer insulating layer 128 and exposing the wordline WL may be formed. The lower portion of the first contact hole Ha may expose the wordline WL

A second contact hole Hb penetrating the insulating liner 152, the first and second interlayer insulating layers 156 and 158, and exposing the peripheral source/drain regions 30 on the peripheral transistors may be formed. The first contact hole Ha and the second contact hole Hb may be formed through the same process, that is, the same etching process.

Referring to FIGS. 3A and 3B together, a barrier layer 162 and a conductive layer 164 may be deposited in order in the first and second openings OP1 and OP2 and the first and second contact holes Ha and Hb. Accordingly, a first upper conductive pattern 160c may be formed in the first opening OP1, and a first dummy structure DS1 may be formed in the second opening OP2. A contact plug 160cp1 may be formed in the first contact hole Ha, and a peripheral contact plug 160cp2 may be formed in the second contact hole Hb. The contact plug 160cp1 and the peripheral contact plug 160cp2 may be formed simultaneously.

The conductive layer formed on the interlayer insulating layer 158 and the first dummy structure DS1 among the conductive layers 164 may be selectively removed, and an insulating material may be deposited, thereby forming the interlayer insulating layer 159.

Thereafter, a patterning process may be performed on the barrier layer 162 and the conductive layer 164, thereby forming insulating patterns 165 penetrating the layers. Thereafter, a capacitor structure including a lower electrode, a capacitor dielectric layer, and an upper electrode may be formed on the first upper conductive pattern 160c.

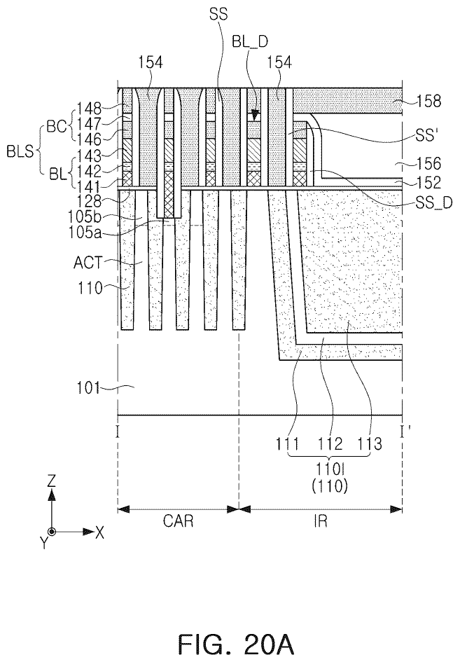

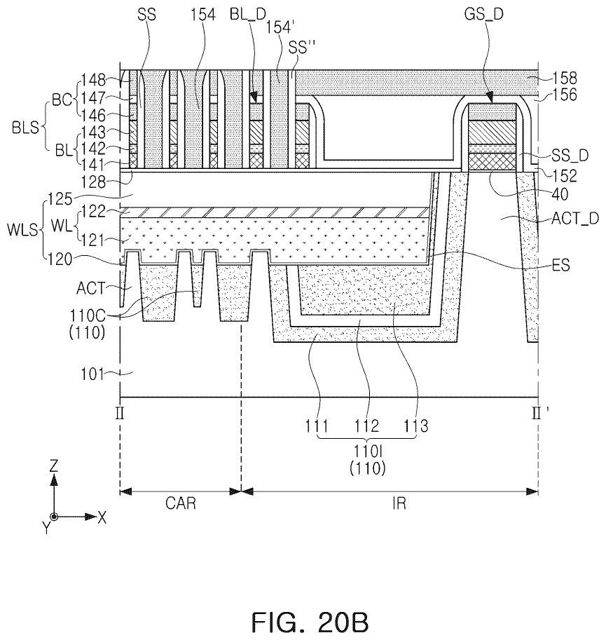

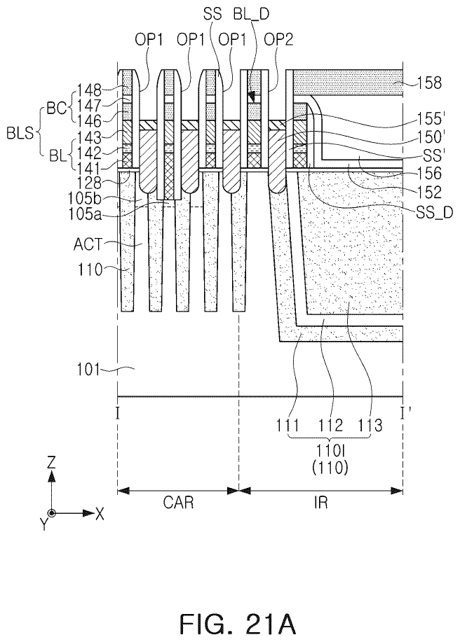

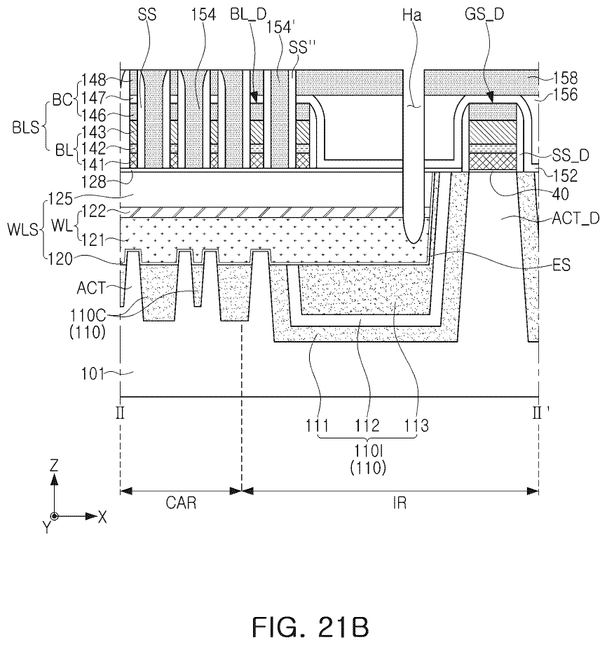

FIGS. 19A and 19B, FIGS. 20A and 20B, and FIGS. 21A and 21B are cross-sectional diagrams illustrating processes of a method of manufacturing a semiconductor device in order according to example embodiments.

Referring to FIGS. 6, 7A, FIGS. 7B, 19A and 19B, a first open regions OR1 may be formed by etching first to third conductive patterns 141, 142, and 143 in order using the first to third capping patterns 146, 147, and 148 as an etching mask by an etching process, and a second open regions OR2 may be formed by etching the interlayer insulating layer 158, the insulating liner 152, and the dummy bitline structure BL_D in order. The first and second open regions OR1 and OR2 may be formed through the same process, that is, the same etching process.

The first open regions OR1 may be substantially the same as or similar to the first open regions OR1 described with reference to FIGS. 16A, 16B, 16C, and 16D, and thus, the detailed description thereof may not be provided.

By the second open region OR2, the dummy bitline structure BL_D may have different widths. Referring to FIG. 6 together, the dummy bitline structure BL_D may have a first width w1. By the second open region OR2, a portion of the dummy bitline structure BL_D may have a second width w2 smaller than the first width w1. The second width w2 may be the width of the dummy bitline structure BL_D of one side of the second open region OR2 in the first direction X.

The second open regions OR2 may include 2-1 open regions OR2a between the wordline structures WL (see FIG. 19A). The second open regions OR2 may include 2-2 open regions OR2b vertically overlapping the wordline structures WL (see FIG. 19B), respectively. The second open regions OR2 may be spaced apart from and aligned in the second direction Y.

Referring to FIGS. 6, 7A, 7B, 20A and 20B, a spacer structure SS and a fence insulating pattern 154 may be formed in the first and second open regions OR1 and OR2. Accordingly, a second dummy structure DS2 may be defined.

The spacer structure SS may be formed on side surfaces of the bitline structure BLS defined by the first open region OR1. The spacer structure SS may also be formed in the second open region OR2. The spacer structure SS may include a plurality of layers.

Fence insulating patterns 154 may be formed between the spacer structures SS. The fence insulating patterns 154 may include silicon nitride or silicon oxynitride. The fence insulating patterns 154 may also be formed in the second open region OR2, and in this case, for ease of description, the fence insulating patterns 154 may be referred to as dummy insulating pattern 154′.

The spacer structure SS and the dummy insulating pattern 154′ formed in a 2-2 open region OR2b among the second open regions OR2 may be defined as the second dummy structure DS2.

Thereafter, a flattening process to remove the step difference (‘Sd’ in FIGS. 19A and 19B) may be optionally performed.

Referring to FIGS. 6, 7A, 7B, 21A and 21B, by performing an anisotropic etching process using the fence insulating patterns 154 and the third capping pattern 148 as etching masks, a first opening OP1 exposing a second impurity region 105b may be formed. The anisotropic etching process may form a second opening OP2 exposing a connection device isolation region 110I using a dummy insulating pattern 154′ as an etching mask.

The first and second openings OP1 and OP2 may be formed between the wordline structures WLS. In another aspect, the first opening OP1 may correspond to the 1-1 open region OR1a, and the second opening OP2 may correspond to the 2-1 open region OR2a.

A conductive material may be formed on a lower portion of each of the first and second openings OP1 and OP2. A lower conductive pattern 150 may be formed in a lower portion of the first opening OP1, and a lower dummy conductive pattern 150′ may be formed in a lower portion of the second opening OP2.

A metal-semiconductor compound may be formed on the conductive material. A metal-semiconductor compound layer 155 may be formed on the lower conductive pattern 150, and a dummy metal-semiconductor compound layer 155′ may be formed on the lower dummy conductive pattern 150′.

A first contact hole Ha penetrating the first and second interlayer insulating layers 156 and 158, the insulating liner 152, and the buffer insulating layer 128, and exposing the wordline WL may be formed. A lower portion of the first contact hole Ha may expose the wordline WL.

A second contact hole Hb penetrating the insulating liner 152, the first and second interlayer insulating layers 156 and 158, and exposing the peripheral source/drain regions 30 may be formed on the peripheral transistors. The first contact hole Ha and the second contact hole Hb may be formed through the same process, that is, the same etching process.

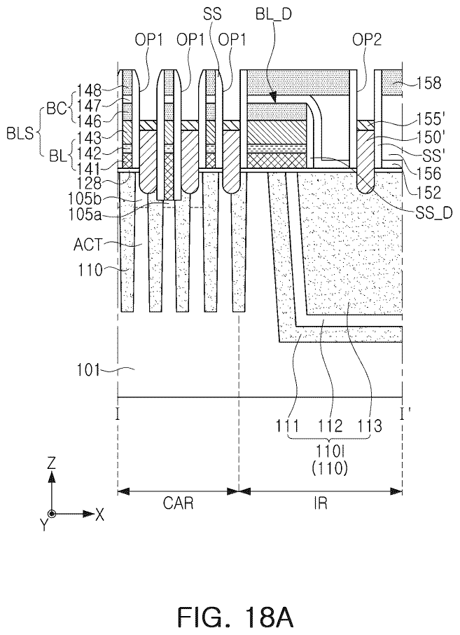

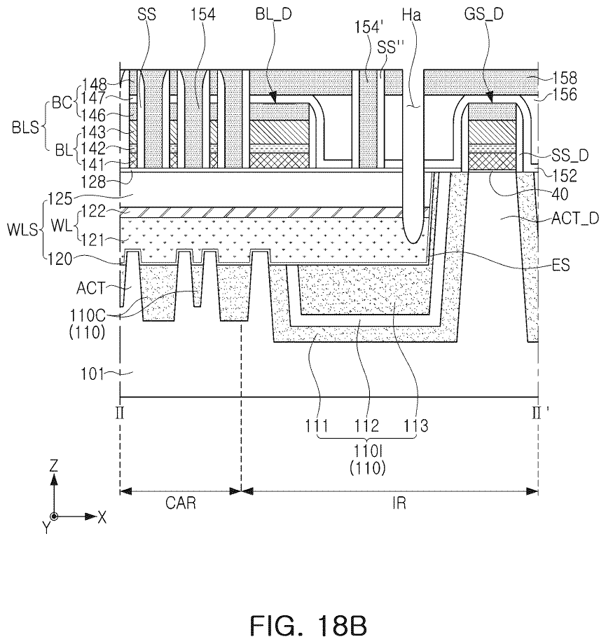

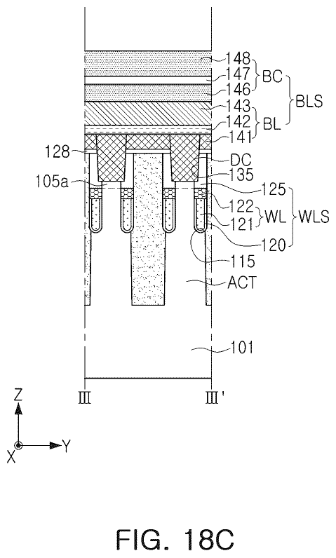

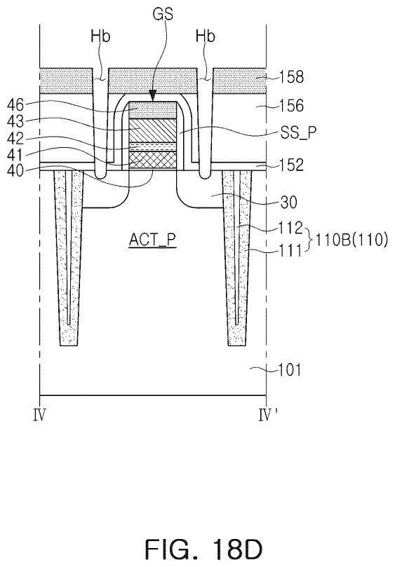

Referring to FIGS. 7A and 7B together, a barrier layer 162 and a conductive layer 164 may be deposited in order in the first and second openings OP1 and OP2 and the first and second contact hole Ha and Hb. Accordingly, a first upper conductive pattern 160c may be formed in the first opening OP1, and a first dummy structure DS1 may be formed in the second opening OP2. A contact plug 160cp1 may be formed in the first contact hole Ha. Similarly to the example described with reference to FIG. 18D, a peripheral contact plug 160cp2 may be formed in the second contact hole (‘Hb’ in FIG. 18D). The contact plug 160cp1 and the peripheral contact plug 160cp2 may be formed simultaneously.

The conductive layer formed on the interlayer insulating layer 158 and the first dummy structure DS1 among the conductive layer 164 may be selectively removed, and an insulating material may be deposited, thereby forming the interlayer insulating layer 159.

Thereafter, by performing a patterning process on the barrier layer 162 and the conductive layer 164, insulating patterns 165 penetrating the layers may be formed. Thereafter, a capacitor structure including a lower electrode, a capacitor dielectric layer, and an upper electrode may be formed on the first upper conductive pattern 160c.

According to the aforementioned example embodiments, a semiconductor device having improved reliability and improved performance and a method of manufacturing the same may be provided.

Also, a semiconductor device including dummy structures on a connection region may be provided.

According to example embodiments of the present disclosure, a method of manufacturing a semiconductor device includes forming a substrate including a cell array region, a peripheral circuit region, and a connection region between the cell array region and the peripheral circuit region; forming a device isolation region including a cell device isolation region defining a cell active region on the cell array region and a connection device isolation region defining an active region on the connection region, on the substrate; forming gate structures including a gate electrode extending in a first direction crossing the cell active region in the cell array region and extending into the connection region, the gate structures being spaced apart from one another in a second direction substantially perpendicular to the first direction; forming a stack structure including a conductive material layer and an insulating material layer on the conductive material layer on the substrate; patterning the stack structure and forming a plurality of open regions, a bitline structure and a dummy bitline structure extending in a second direction intersecting the gate structures, the plurality of open regions including a first open region defining a side surface of the bitline structure on the cell array region, and a second open region penetrating the dummy bitline structure on the connection region; and forming a dummy structure in the second open region.

The second open region may include a 2-1 open region between the gate structures; and a 2-2 open region vertically overlapping each of the gate structures.

The 2-1 and 2-2 open regions may be spaced apart from one another and aligned in the second direction.

The forming the dummy structure may include forming a first dummy structure in the 2-1 open region; and forming a second dummy structure in the 2-2 open region.

The forming the first dummy structure may include forming a first dummy spacer structure on a sidewall of the 2-1 open region; and forming a dummy insulating material layer covering the first dummy spacer structure in the 2-1 open region.

A level of an upper surface of the first dummy structure may be higher than a level of an upper surface of the dummy bitline structure.

The forming of the second dummy structure may include forming a second dummy spacer structure on the sidewall of the 2-2 open region; and forming at least one conductive material layer in the 2-2 open region.

A level of an upper surface of the second dummy structure may be higher than a level of an upper surface of the dummy bitline structure.

In a planar view, the first and second open regions may have at least one of a polygonal shape or a circular shape.

The method may further include forming a gate contact plug connected to the gate electrode and an upper portion conductive pattern on the gate contact plug on the connection region.

While example embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a substrate including a cell array region, a peripheral circuit region, and a connection region between the cell array region and the peripheral circuit region;
a device isolation region including a cell device isolation region defining a cell active region on the cell array region and a connection device isolation region defining an active region on the connection region, on the substrate;
a gate structure including a gate electrode crossing the cell active region on the cell array region and extending into the connection device isolation region of the device isolation region on the connection region;
a bitline structure extending in a first direction intersecting the gate structure on the cell array region and connected to the cell active region;
a dummy bitline structure extending in the first direction on the connection region and having at least a portion disposed at substantially a same level as a level of the bitline structure;
an insulating structure disposed on the dummy bitline structure on the connection region; and
dummy structures disposed on the connection region and extending through at least a portion of the insulating structure,
wherein the dummy structures include:
a first dummy structure disposed on the connection device isolation region; and
a second dummy structure spaced apart from the first dummy structure in the first direction, vertically overlapping the gate structure, and having at least a portion disposed at substantially a same level as a level of the bitline structure.

2. The semiconductor device of claim 1,
wherein:
the insulating structure covers an upper portion of the dummy bitline structure, and
a level of an upper surface of each of the first and second dummy structures is substantially the same as a level of an upper surface of the insulating structure.

3. The semiconductor device of claim 2, wherein a level of the upper surface of the each of the first and second dummy structures is higher than a level of an upper surface of the dummy bitline structure.

4. The semiconductor device of claim 1,
wherein:
the cell active region includes a first impurity region and a second impurity region,
the bitline structure is connected to the first impurity region, and
the semiconductor device further includes:
a lower conductive pattern connected to the second impurity region;
a first upper conductive pattern on the lower conductive pattern; and
a capacitor structure on the first upper conductive pattern.

5. The semiconductor device of claim 4, further comprising:
a gate contact plug connected to the gate electrode, on the connection region;
and
a second upper conductive pattern on the gate contact plug,
wherein upper surfaces of the first and second upper conductive patterns are substantially at a same level.

6. The semiconductor device of claim 4, wherein the first dummy structure includes:
a dummy conductive pattern; and
a first dummy spacer structure surrounding a side surface of the dummy conductive pattern.

7. The semiconductor device of claim 6, wherein lower surfaces of the lower conductive pattern and the dummy conductive pattern are substantially at a same level.

8. The semiconductor device of claim 1, further comprising:
a fence insulating pattern on one side of the bitline structure,
wherein the second dummy structure includes:
a dummy insulating pattern extending in a vertical direction; and
a second dummy spacer structure surrounding a side surface of the dummy insulating pattern, and
wherein lower surfaces of the fence insulating pattern and the dummy insulating pattern are substantially at a same level.

9. The semiconductor device of claim 1, wherein the first dummy structure extends through the insulating structure and extends into at least a portion of the connection device isolation region.

10. The semiconductor device of claim 1, wherein the first and second dummy structures extend through the insulating structure and the dummy bitline structure.

11. The semiconductor device of claim 1, wherein, in planar view, the dummy structures have at least one of a polygonal shape or a circular shape.

12. A semiconductor device, comprising:
a substrate including a cell array region having a cell active region, a peripheral circuit region, and a connection region between the cell array region and the peripheral circuit region;
gate structures including a gate electrode extending in a first direction crossing the cell active region on the cell array region and extending into the connection region, the gate structures being spaced apart from one another in a second direction substantially perpendicular to the first direction;
a bitline structure extending in the second direction intersecting the gate structures on the cell array region, and connected to the cell active region;
a dummy bitline structure extending in the second direction on the connection region;
an insulating structure including an insulating liner covering an upper portion and a side portion of the dummy bitline structure and extending along upper surfaces of the gate structures, and an interlayer insulation layer on the insulating liner; and
dummy patterns on the connection region,
wherein the dummy patterns include:
at least one first dummy pattern extending through the insulating structure and the dummy bitline structure between the gate structures; and
at least one second dummy pattern vertically overlapping the gate structures and extending through the insulating structure and the dummy bitline structure.

13. The semiconductor device of claim 12, wherein the at least one first dummy pattern and the at least one second dummy pattern are aligned in the second direction.

14. £ The semiconductor device of claim 12, wherein the at least one first dummy pattern includes:
a dummy conductive pattern; and
a first dummy spacer structure surrounding a side surface of the dummy conductive pattern and in contact with the dummy bitline structure and the insulating structure.

15. The semiconductor device of claim 14, wherein a level of a lower surface of the dummy conductive pattern is lower than a level of a lower surface of the first dummy spacer structure.

16. The semiconductor device of claim 12, wherein the at least one second dummy pattern includes:
a dummy insulating pattern extending in a vertical direction; and
a second dummy spacer structure surrounding a side surface of the dummy insulating pattern and in contact with the dummy bitline structure and the insulating structure.

17. The semiconductor device of claim 12, further comprising:
an interlayer insulating layer on the first dummy pattern;
an upper conductive pattern on the second dummy pattern; and
a gate contact plug extending downwardly from the upper conductive pattern on the connection region and connected to the gate electrode, and
wherein upper surfaces of the upper conductive pattern and the interlayer insulating layers are substantially at a same level.

18. The semiconductor device of claim 12,
wherein the at least one first dummy pattern includes a plurality of first dummy patterns spaced apart from one another in the first direction, and
wherein the at least one second dummy pattern includes a plurality of second dummy patterns spaced apart from one another in the first direction.

19. A semiconductor device, comprising:
a substrate having a cell array region having a cell active region, a peripheral circuit region, and a connection region between the cell array region and the peripheral circuit region;
gate structures including a gate electrode extending in a first direction crossing the cell active region on the cell array region and extending into the connection region, each of the gate structures being spaced apart from one another in a second direction substantially perpendicular to the first direction;
a bitline structure extending in the second direction intersecting the cell array region and connected to the cell active region;
a dummy bitline structure extending in the second direction on the connection region;
dummy structures disposed on the connection region and penetrating the dummy bitline structure,
wherein the dummy bitline structure has different widths taken in the first direction along the second direction.

20. The semiconductor device of claim 19, wherein the dummy bitline structure includes:
a first portion having a first width greater than a width in the first direction of the bitline structure; and
a second portion having a second width less than the first width.
